(19) United States
(12) Patent Application Publication
(10) Pub. No.: US 2018/0254015 A1
(43) Pub. Date: Sep. 6, 2018

(54) LIQUID CRYSTAL DISPLAY DEVICE AND METHOD FOR DRIVING SAME

(71) Applicant: Sharp Kabushiki Kaisha, Sakai City, Osaka (JP)

(72) Inventors: Tatsuhiko SUYAMA, Sakai City (JP); Takuya SONE, Sakai City (JP); Noriyuki TANAKA, Sakai City (JP); Kazuki TAKAHASHI, Sakai City (JP)

(21) Appl. No.: 15/759,241

(22) PCT Filed: Sep. 7, 2016
(86) PCT No.: PCT/JP2016/076275

§ 371 Date: Mar. 12, 2018

(30) Foreign Application Priority Data
Sep. 14, 2015 (JP) 2015-180418

(51) Int. Cl. G09G 3/36; G02F 1/1368; H01L 27/12; H01L 29/24; H01L 29/786; G02F 1/1362

(52) U.S. Cl. CPC G09G 3/3688; G02F 1/1368; H01L 27/1225; H01L 27/1255; H01L 29/24; G09G 2300/0823; H01L 29/7869; H01L 27/124; G02F 1/136286; G02F 2202/10; G09G 2310/0272; H01L 29/78696

(57) ABSTRACT

Provided are a liquid crystal display device capable of keeping power consumption low and preventing a polarity bias, and a method for driving the same. In a liquid crystal display device (100), for example, when five forced refreshes are performed, a special refresh, which involves no polarity inversion, is performed as one of the five, provided that an occurrence rate of a limit refresh during a Y-frame period, which is set to be a given period of time, exceeds a predetermined threshold. Accordingly, a polarity bias value Nb approaches “0”, whereby the need to perform a further limit refresh is eliminated, resulting in a decreased number of refreshes. Thus, the total power consumption by refreshes during a limit refresh period T3 can be made lower than can be conventionally made.

### TECHNICAL FIELD

The present invention relates to liquid crystal display devices and methods for driving the same, particularly to a liquid crystal display device capable of image display by pause drive and a method for driving the same.

### BACKGROUND ART

It is often the case that low power consumption and thin liquid crystal display devices are employed for displays of portable electronic apparatuses such as smartphones and tablets. As an example of such a liquid crystal display device, Patent Document 1 discloses a liquid crystal display device whose refresh rate changes in accordance with an image to be displayed. Specifically, when a video is displayed, the liquid crystal display device is driven with an increased refresh rate, and when a still image is displayed, pause drive is performed so as to reduce power consumption. In order not to cause a polarity bias in each pixel forming portion when switching between refresh rates, the liquid crystal display device manages the duration in which a positive data signal is written and the duration in which a negative data signal is written, and if the difference therebetween becomes excessively significant, a limit refresh to be described later is performed. In this manner, the liquid crystal display device is designed not to cause an excessive polarity bias.

### CITATION LIST

### Patent Document

Patent Document 1: International Publication WO 2013/125406

### SUMMARY OF THE INVENTION

### Problems to be Solved by the Invention

However, in the case of liquid crystal display devices whose refresh rates change when a predetermined condition is satisfied, as in the case of the liquid crystal display device described in Patent Document 1, no refresh is performed until the condition is satisfied, but by then, a polarity bias occurs. On the other hand, if a limit refresh is repeated in order to prioritize eliminating a polarity bias, the number of refreshes increases, resulting in increased power consumption.

Therefore, an objective of the present invention is to provide a liquid crystal display device capable of keeping power consumption low and preventing a polarity bias, and a method for driving the same.

### Solution to the Problems

A first aspect of the present invention is directed to a liquid crystal display device for displaying an image represented by input image data on a display portion by applying data voltages to a liquid crystal layer of the display portion in accordance with the image data, the device comprising:

a drive portion configured to apply the data voltage to the liquid crystal layer; and

a display control portion configured to manage a polarity bias of the data voltage for each predetermined period and controlling the drive portion so as to lessen the polarity bias by a forced refresh updating an image displayed on the display portion;

the display portion including a plurality of pixels forming portions configured to hold the data voltages, wherein,

when a polarity bias value indicating the polarity bias reaches a preset limit, the display control portion rewrites the data voltage held in the pixel forming portion such that the data voltage is inverted in polarity, determines whether a frequency of the polarity bias value reaching the limit satisfies a predetermined condition, and when the predetermined condition is determined to be satisfied, controls the drive portion such that the data voltage is rewritten without being inverted in polarity by the forced refresh being performed immediately after the satisfaction of the predetermined condition.

In a second aspect of the present invention, based on the first aspect of the present invention, wherein,

the display control portion includes:
a polarity bias management circuit configured to obtain and manage the polarity bias value for each of the predetermined periods and outputs a limit-hit signal when the polarity bias value reaches the limit;
a polarity inversion control circuit configured to generate and output a polarity signal to perform control such that the polarity bias value outputted by the polarity bias management circuit approaches “0” by means of the forced refresh when the polarity bias value does not reach the limit or the polarity bias value is inverted when the polarity bias value reaches the limit; and
a timing control circuit configured to generate and provide a refresh signal to the polarity bias management circuit and the polarity inversion control circuit upon reception of a forced refresh signal for the forced refresh or generate and provide a limit refresh signal to the polarity bias management circuit and the polarity inversion control circuit upon reception of the limit-hit signal,

the timing control circuit determines whether the frequency of receiving the limit-hit signal satisfies the predetermined condition, and generates and provides an occurrence frequency signal to the polarity inversion control circuit when the predetermined condition is determined to be satisfied, and

upon provision of the occurrence frequency signal, the polarity inversion control circuit performs control such that the forced refresh in conformity with the image data is performed with the same polarity as an immediately preceding refresh.

In a third aspect of the present invention, based on the second aspect of the present invention, wherein,

the timing control circuit includes a limit counter configured to count the number of receptions of the limit-hit signal, a threshold register configured to memorize a threshold of the number of receptions of the limit-hit signal, and a comparison circuit configured to compare the number of receptions of the limit-hit signal and the threshold, and

when the number of receptions of the limit-hit signal memorized by the limit counter is determined to be greater than or equal to the threshold memorized by the threshold register as a result of the comparison circuit comparing the number of receptions of the limit-hit signal and the threshold, the timing control circuit outputs the occurrence frequency signal to the polarity inversion control circuit.

In a fourth aspect of the present invention, based on the third aspect of the present invention, wherein the timing control circuit further includes a refresh counter configured to count the number of receptions of the forced refresh signal, obtains an occurrence frequency on the basis of the number of receptions memorized by the limit counter and the number of receptions memorized by the refresh counter, compares the occurrence frequency and the threshold memorized by the threshold register by means of the comparison circuit, and when the occurrence frequency is determined to be greater than or equal to the threshold, outputs the occurrence frequency signal to the polarity inversion control circuit.

In a fifth aspect of the present invention, based on the forth aspect of the present invention, wherein the refresh counter counts the number of receptions of the forced refresh signal and the number of receptions of the limit refresh signal and obtains a total number of receptions.

In a sixth aspect of the present invention, based on the third aspect of the present invention, wherein the timing control circuit further includes a Y-frame register configured to memorize a period of time being set as a Y-frame period, reads out the period being set as the Y-frame period from the Y-frame register, sets the Y-frame period to extend back from an arbitrary point in time within a period during which the forced refresh is performed, and determines whether the occurrence frequency is greater than or equal to the threshold during the Y-frame period.

In a seventh aspect of the present invention, based on the second aspect of the present invention, wherein,

the timing control circuit includes a Z-frame register configured to memorize a period of time being set as a Z-frame period, and

upon reception of a limit refresh signal from the polarity bias management circuit, the timing control circuit reads out the period being set as the Z-frame period from the Z-frame register, sets the Z-frame period to extend forward, and upon reception of an initial limit refresh signal during the Z-frame period, outputs the occurrence frequency signal to the polarity inversion control circuit.

In an eighth aspect of the present invention, based on the second aspect of the present invention, wherein the polarity bias management circuit includes a balance counter configured to count and hold the polarity bias value, and increases or decreases the polarity bias value held in the balance counter by “1” as specified by the polarity signal upon each provision of a vertical synchronization signal to display an image represented by the image data on the display portion.

In a ninth aspect of the present invention, based on the second aspect of the present invention, further comprising a positive gamma circuit configured to generate positive image data on the basis of the image data and a negative gamma circuit configured to generate negative image data on the basis of the input image data, wherein,

the display control portion further includes a selector configured to select either the positive gamma circuit or the negative gamma circuit, and

the selector selects either the positive gamma circuit or the negative gamma circuit in accordance with the polarity signal provided by the polarity inversion control circuit, and provides the input image data so as not to cause a polarity bias in each of the pixel forming portions.

In a tenth aspect of the present invention, based on the ninth aspect of the present invention, wherein,

the display control portion further includes frame memory configured to store the input image data,

the timing control circuit outputs the refresh signal to the polarity inversion control circuit and the polarity bias management circuit, and provides the frame memory with a readout signal to read out the image data, and

the frame memory outputs to the selector the image data having already been stored upon provision of the readout signal.

In an eleventh aspect of the present invention, based on the second aspect of the present invention, further comprising data signal lines and scanning signal lines formed on the display portion so as to connect the pixel forming portions and the drive portion, wherein,

the pixel forming portion includes:
a pixel capacitor configured to hold the data voltage; and
a switching element with a control terminal connected to the scanning signal line, a first conductive terminal connected to the data signal line, and a second conductive terminal connected to the pixel capacitor, and

the switching element includes a thin-film transistor with a channel layer formed with an oxide semiconductor.

In a twelfth aspect of the present invention, based on the eleventh aspect of the present invention, wherein the pixel forming portion includes a thin-film transistor with an oxide semiconductor layer.

In a thirteenth aspect of the present invention, based on the twelfth aspect of the present invention, wherein the thin-film transistor is a channel-etched thin-film transistor.

In a fourteenth aspect of the present invention, based on the twelfth aspect of the present invention, wherein the oxide semiconductor layer is formed with indium gallium zinc oxide.

In a fifteenth aspect of the present invention, based on the twelfth aspect of the present invention, wherein the oxide semiconductor layer is formed with a crystalline oxide semiconductor.

In a sixteenth aspect of the present invention, based on the twelfth aspect of the present invention, wherein the oxide semiconductor layer is formed with a crystalline oxide semiconductor.

A seventeenth aspect of the present invention is directed to a method for driving a liquid crystal display device displaying an image represented by input image data on a display portion by applying data voltages to a liquid crystal layer of the display portion in accordance with the image data, the device including a drive portion configured to apply the data voltage to the liquid crystal layer, and a display control portion configured to manage a polarity bias of the data voltage for each predetermined period and controlling the drive portion so as to lessen the polarity bias of the data voltage during a frame period in which the image displayed on the display portion is updated, the display portion including a plurality of pixel forming portions configured to hold the data voltages, the method comprising the steps of:

when a polarity bias value indicating the polarity bias reaches a preset limit, rewriting the data voltage held in the pixel forming portion such that the data voltage is inverted in polarity;

determining whether the polarity bias value satisfies a predetermined condition; and

when the predetermined condition is determined to be satisfied, controlling the drive portion such that the data voltage is rewritten without being inverted in polarity by a forced refresh being performed immediately after a limit refresh, in accordance with updating the image data.

### Effect of the Invention

In the first aspect of the present invention, when the polarity bias value reaches the preset limit, the data voltage held in the pixel forming portion is rewritten such that the polarity thereof is inverted, and further, whether the frequency of the polarity bias value reaching the limit satisfies a predetermined condition. As a result, if the predetermined condition is determined to be satisfied, a forced refresh is performed immediately after the satisfaction of the condition, such that the data voltage is rewritten without being inverted in polarity. Accordingly, the polarity bias value moves away from the limit, whereby the need to perform a further limit refresh is eliminated, resulting in a decreased number of limit refreshes. Thus, the total power consumption by refreshes during the limit refresh period can be made lower than can be conventionally made.

In the second aspect of the present invention, when the frequency of receiving the limit-hit signal outputted by the polarity bias management circuit is determined to satisfy a predetermined condition, the timing control circuit provides an occurrence frequency signal to the polarity inversion control circuit. Accordingly, the polarity inversion control circuit performs a forced refresh with the same polarity as an immediately preceding refresh. As a result, the polarity bias value moves away from the limit, whereby the need to perform a further limit refresh is eliminated, resulting in a decreased number of limit refreshes. Thus, the total power consumption by refreshes during the limit refresh period can be made lower than can be conventionally made.

In the third aspect of the present invention, when determining whether to perform a refresh which involves no polarity inversion, the number of receptions of the limit refresh signal is directly compared to the threshold, and therefore, there is no need to provide a counter for counting the number of receptions of refresh signals, including the forced refresh signal. This allows a simplified circuit configuration of the timing control circuit, resulting in a reduced cost of the liquid crystal display device.

In the fourth aspect of the present invention, the liquid crystal display device uses the Y-frame register, the threshold register, the limit counter, the refresh counter, and the comparison circuit to determine whether to perform a forced refresh which involves no polarity inversion, and therefore, an erroneous determination which causes polarity inversion, even though polarity inversion is unnecessary, is less likely to occur. Thus, it is possible to inhibit power consumption from increasing due to another limit refresh being performed.

In the fifth aspect of the present invention, the refresh counter counts the number of receptions of the forced refresh signal and the number of receptions of the limit refresh signal and obtains a total number of receptions. Thus, the occurrence frequency of the limit refresh can be grasped more accurately.

In the sixth aspect of the present invention, when the occurrence frequency of the limit refresh during a Y-frame period, which is set to be a given period of time, is greater than or equal to a predetermined threshold, a forced refresh is performed without causing polarity inversion. As a result, the polarity bias value moves away from the limit, whereby the need to perform a further limit refresh is eliminated, resulting in a decreased number of limit refreshes. Thus, the total power consumption by refreshes can be made lower than can be conventionally made.

In the seventh aspect of the present invention, the timing control circuit, which determines whether to perform a forced refresh which involves no polarity inversion, has a simplified configuration when compared to the fourth and fifth aspects of the present invention. Accordingly, even if polarity inversion should be performed, a determination to not cause polarity inversion might be made, resulting in an increased number of limit refreshes and hence increased power consumption, but the cost of producing the liquid crystal display device can be kept low.

In the eighth aspect of the present invention, upon each provision of a vertical synchronization signal, the polarity bias value held in the balance counter is incremented or decremented by “1” as specified by a polarity signal. Thus, the polarity bias management circuit can reliably count the polarity bias value corresponding to charge polarization caused in the pixel forming portion.

In the ninth aspect of the present invention, the positive gamma circuit, which generates positive image data, and the negative gamma circuit, which generates negative image data, are provided so as to be selectable by the selector. Therefore, focusing on one pixel forming portion to which positive image data is provided, input image data is provided to the positive gamma circuit so as to perform control such that the polarity bias value increases, or input image data is provided to the negative gamma circuit so as to perform control such that the polarity bias value decreases. Note that image data for one display screen includes not only pieces of positive image data but also the same number of pieces of negative image data. Accordingly, focusing on another pixel forming portion to which negative image data is provided, input image data is provided to the negative gamma circuit so as to perform control such that the polarity bias value increases, or input image data is provided to the positive gamma circuit so as to perform control such that the polarity bias value decreases. As a result, in either case, a polarity bias of the voltage applied to the liquid crystal layer can match the polarity bias value managed by the polarity bias management circuit.

In the tenth aspect of the present invention, image data transmitted from the host is stored to the frame memory, and can be read out by providing a readout signal to the frame memory when a refresh signal is outputted by the timing control circuit. Thus, the image data can be read out from the frame memory at the time of updating the image displayed on the display portion, with the result that that the image updating can be performed readily.

In the eleventh aspect of the present invention, each pixel forming portion of the liquid crystal display device, which is of an active matrix type, has a switching element for which a thin-film transistor with a channel layer formed with an oxide semiconductor is used. Accordingly, the thin-film transistor has a significantly reduced off-leakage current, with the result that a voltage written in the pixel capacitor in the pixel forming portion can be held for a long period of time. Moreover, by applying an alternating-current voltage to the liquid crystal layer, it is rendered possible to reduce a polarity bias of the applied voltage by controlling the drive portion after the time at which an off signal is inputted. Thus, in the case where pause drive and low-frequency drive are performed, it is possible to inhibit, for example, the occurrence of flickering while significantly reducing power consumption for image display.

In any of the twelfth through sixteenth aspects of the present invention, by using thin-film transistors with oxide semiconductor layers, it is rendered possible to maintain display quality while significantly decreasing the number of times the display panel is driven, as well as power consumption by the display device.

The seventeenth aspect of the present invention renders it possible to achieve effects similar to those achieved by the first aspect.

### BRIEF DESCRIPTION OF THE DRAWINGS

FIG. 1 is a timing chart describing pause drive of a liquid crystal display device.

FIG. 2 is a block diagram illustrating the configuration of a liquid crystal display device according to a first embodiment of the present invention.

FIG. 3 is a block diagram illustrating the configuration of a display control portion included in the liquid crystal display device in the present embodiment.

FIG. 4 is a diagram illustrating changes of a polarity bias value for a conventional liquid crystal display device where refreshes are repeated.

FIG. 5 is a diagram illustrating changes of the polarity bias value for the liquid crystal display device according to the first embodiment of the present invention where a special refresh is performed.

FIG. 6 is a diagram illustrating power consumption by a conventional liquid crystal display device.

FIG. 7 is a diagram illustrating power consumption by the liquid crystal display device according to the first embodiment of the present invention.

FIG. 8 is a block diagram illustrating the configuration of a display control portion included in a liquid crystal display device according to a second embodiment of the present invention.

FIG. 9 is a diagram illustrating changes of a polarity bias value for the liquid crystal display device according to the second embodiment of the present invention where a special refresh is performed.

FIG. 10 is a block diagram illustrating the configuration of a display control portion included in a liquid crystal display device according to a third embodiment of the present invention.

FIG. 11 is a diagram illustrating changes of a polarity bias value for the liquid crystal display device according to the third embodiment of the present invention where a special refresh is performed.

FIG. 12 is a diagram illustrating the structure of a channel-etched TFT.

### MODES FOR CARRYING OUT THE INVENTION

### 0. Basic Study

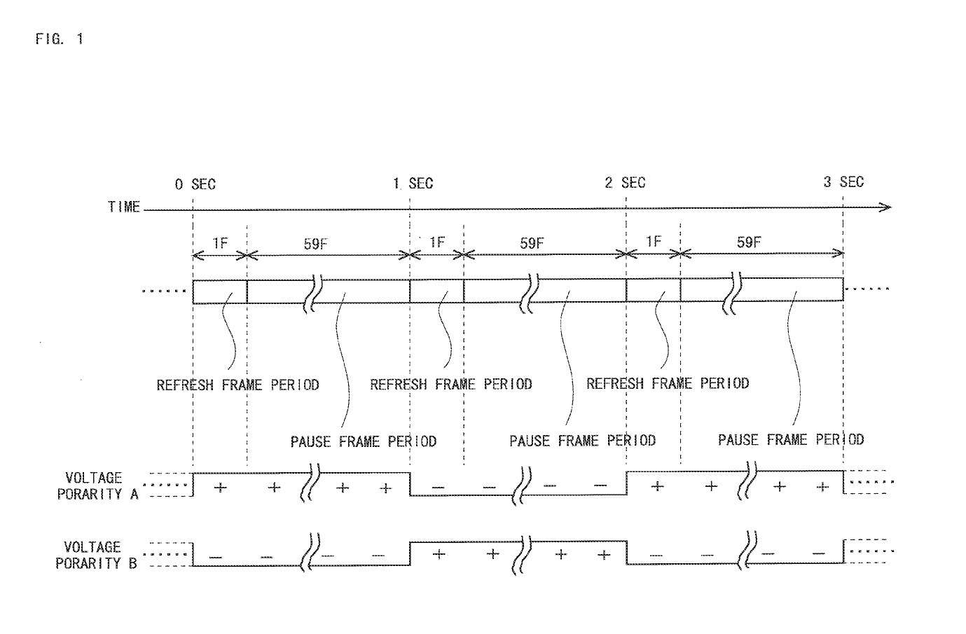

The problem for the present invention, i.e., a biased polarity of a voltage applied to a liquid crystal layer (also referred to simply as a “polarity bias”), is caused by pause drive, and therefore, pause drive will be described first. FIG. 1 is a timing chart describing pause drive of a liquid crystal display device. In this example, a data voltage for one screen is written during a frame period, and the writing of the data voltage is paused during 59 subsequent frame periods. That is, a display portion of the liquid crystal display device is driven such that one refresh frame period alternates with 59 pause frame periods (pause drive periods). Accordingly, the refresh rate is 1 Hz, and the refresh cycle is one second.

In this example, a data voltage to be written to a pixel forming portion is inverted in polarity every refresh frame period. In FIG. 1, voltage polarity A indicates the polarity of a data voltage written to a pixel forming portion (i.e., the voltage being held in a pixel capacitor within the pixel forming portion), and voltage polarity B indicates the polarity of a data voltage written to another pixel forming portion during the same frame period. As can be appreciated from voltage polarities A and B shown in FIG. 1, the data voltage held in the pixel capacitor within each pixel forming portion is inverted in polarity every second, and therefore, a data voltage applied to a liquid crystal layer is also inverted in polarity every second. Accordingly, the polarity inversion cycle of the data voltage applied to the liquid crystal layer (hereinafter referred to simply as the “inversion cycle”) is considerably longer than one frame period (16.67 ms), which is the inversion cycle for general liquid crystal display devices in which no pause drive is performed.

The liquid crystal display device displays an image by controlling the optical transmittance of the liquid crystal layer through application of a voltage to the liquid crystal layer. When the voltage applied to the liquid crystal layer contains a direct-current component, charge accumulation (also referred to as “charge polarization”) occurs due to impurity ions being unevenly distributed in the liquid crystal layer, resulting in display failures such as flickering and afterimage. To inhibit the occurrence of such display failures, the liquid crystal display device performs alternating-current drive. By performing alternating-current drive, the voltage applied to the liquid crystal layer is inverted in polarity every predetermined period (typically every frame period), as in the case of voltage polarities A and B shown in FIG. 1, so that the temporal average (or integral value) for the voltage applied to the liquid crystal layer can be essentially “0”.

Furthermore, the polarity bias refers to the difference between the sum of periods during which a positive data voltage is held in a pixel forming portion and the sum of periods during which a negative data voltage is held in the pixel forming portion. For example, in the case where one frame period is used as a unit to represent the degree of polarity bias, the degree of polarity bias is expressed by the difference between the sum of frame periods during which a positive voltage is applied to a location on a liquid crystal layer and the sum of frame periods during which a negative voltage is applied to the same location, and when the difference is “0”, it can be said that there is no polarity bias. Note that “charge polarization” corresponds to “polarity bias”, and both represent the same state.

### 1. First Embodiment

<1.1 General Configuration and Operation Outline>

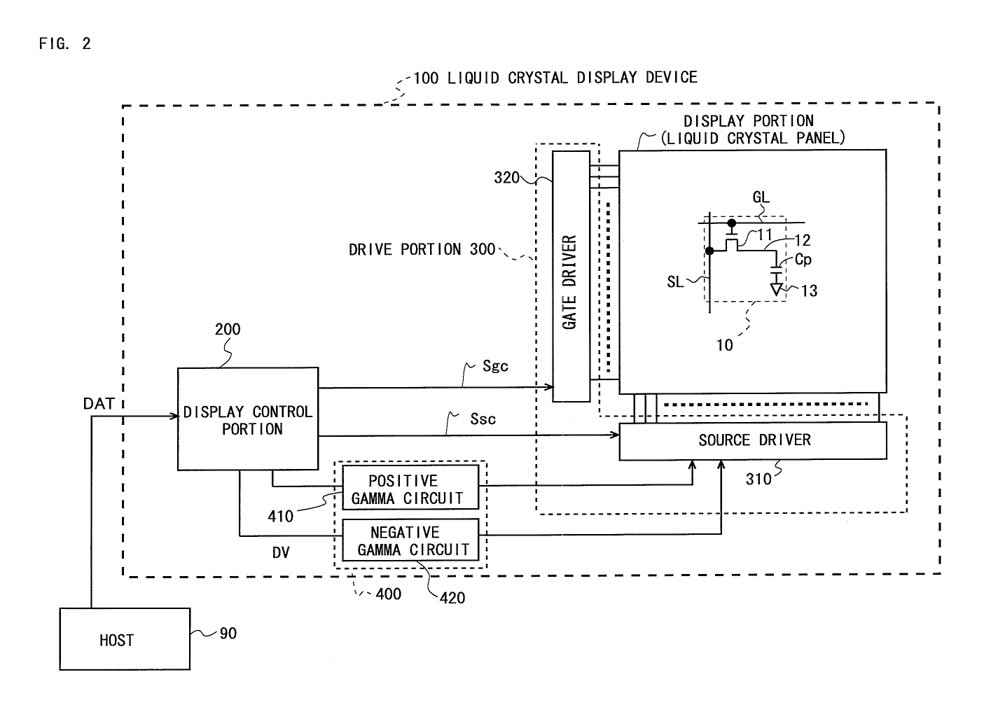

FIG. 2 is a block diagram illustrating the configuration of a liquid crystal display device 100 according to a first embodiment of the present invention. The liquid crystal display device 100 includes a display control portion 200, a drive portion 300, a gamma portion 400, and a display portion 500. The drive portion 300 includes a source driver 310 serving as a data signal line driver circuit and a gate driver 320 serving as a scanning signal line driver circuit. The gamma portion 400 includes a positive gamma circuit 410, which outputs image data DV included in data DAT transmitted from a host 90, to the source driver 310 as positive image data DV, and a negative gamma circuit 420, which outputs the image data DV to the source driver 310 as negative image data DV. The display portion 500 includes a liquid crystal panel, which may be integrally formed with either the source driver 310 or the gate driver 320, or both. The host 90, which is mainly composed of a CPU (central processing unit), is provided outside the liquid crystal display device 100. The host 90 provides the liquid crystal display device 100 with, for example, the data DAT, which includes the image data DV, a command required for displaying an image on the display portion 500, and an off-sequence signal, which is given at the time of power off.

The display portion 500 has formed thereon a plurality of data signal lines SL, a plurality of scanning signal lines GL, and a plurality of pixel forming portions 10 disposed in a matrix corresponding to the data signal lines SL and the scanning signal lines GL. For the sake of convenience, FIG. 2 shows only one pixel forming portion 10 along with one data signal line SL and one scanning signal line GL which correspond thereto. Each pixel forming portion 10 includes a thin-film transistor (TFT) 11, which has a gate terminal (also referred to as a “control terminal”) connected to a corresponding scanning signal line GL and a source terminal (also referred to as a “first conductive terminal”) connected to a corresponding data signal line SL, a pixel electrode 12 connected to a drain terminal (also referred to as a “second conductive terminal”) of the TFT 11, a common electrode 13 provided in common for the pixel forming portions 10, and a liquid crystal layer provided in common for the pixel forming portions 10 between the pixel electrode 12 and the common electrode 13. Moreover, the pixel electrode 12 and the common electrode 13 form a liquid crystal capacitor, which is included in a pixel capacitor Cp. Note that to reliably hold a voltage in the pixel capacitor Cp, an auxiliary capacitor is typically provided in parallel to the liquid crystal capacitor, and therefore, in actuality, the pixel capacitor Cp includes the liquid crystal capacitor and the auxiliary capacitor. Also, the TFT 11 is simply required to be a TFT whose channel layer is made with amorphous silicon, polycrystalline silicon, or an oxide semiconductor. However, considering use in the liquid crystal display device capable of pause drive, a low off-leakage current is preferable, and therefore, the TFT whose channel layer is made with an oxide semiconductor is most suitable. Accordingly, the TFT whose channel layer is made with an oxide semiconductor is used in each embodiment of the present invention, and will be described in detail later.

The display control portion 200 is typically realized by an IC (integrated circuit). Upon reception of data DAT, which includes image data DV representing an image to be displayed, from the host 90, the display control portion 200 generates and outputs a source driver control signal Ssc, a gate driver control signal Sgc, a common voltage signal, etc. The source driver control signal Ssc is provided to the source driver 310, the gate driver control signal Sgc is provided to the gate driver 320, and the common voltage signal is provided to the common electrode 13 provided in the display portion 500. Note that the display control portion 200, the drive portion 300, and the gamma portion 400 in FIG. 2 may be provided on one chip.

In response to the source driver control signal Ssc, the source driver 310 generates and outputs a data voltage to be provided to each data signal line SL, on the basis of positive image data DV provided by the positive gamma circuit 410 or negative image data DV provided by the negative gamma circuit 420. The source driver control signal Ssc includes, for example, a source start pulse signal, a source clock signal, and a latch strobe signal. In accordance with such a source driver control signal Ssc, the source driver 310 generates the data voltage by activating unillustrated internal elements, such as a shift register and a sampling latch circuit, and converting the image data DV into an analog signal by means of an unillustrated D/A conversion circuit. Moreover, the source driver 310 includes an unillustrated amplifier for amplifying a positive data voltage (referred to as a “positive amplifier”) and an unillustrated amplifier for amplifying a negative data voltage (referred to as a “negative amplifier”), and the data voltage is amplified by an amplifier selected in accordance with the polarity thereof and outputted to the display portion 500.

In response to the gate driver control signal Sgc, the gate driver 320 repeats application of an active scanning signal to each scanning signal line GL in a predetermined cycle. The gate driver control signal Sgc includes, for example, a gate clock signal and a gate start pulse signal. The gate driver 320 generates the scanning signal by activating an unillustrated shift register and other internal elements in accordance with the gate clock signal and the gate start pulse signal.

In this manner, the data voltage is applied to each data signal line SL, and the scanning signal is applied to each scanning signal line GL, with the result that the image represented by the image data DV, which is included in the data DAT transmitted from the host 90, is displayed on the display portion 500, i.e., the liquid crystal panel.

<1.2 Configuration of the Display Control Portion>

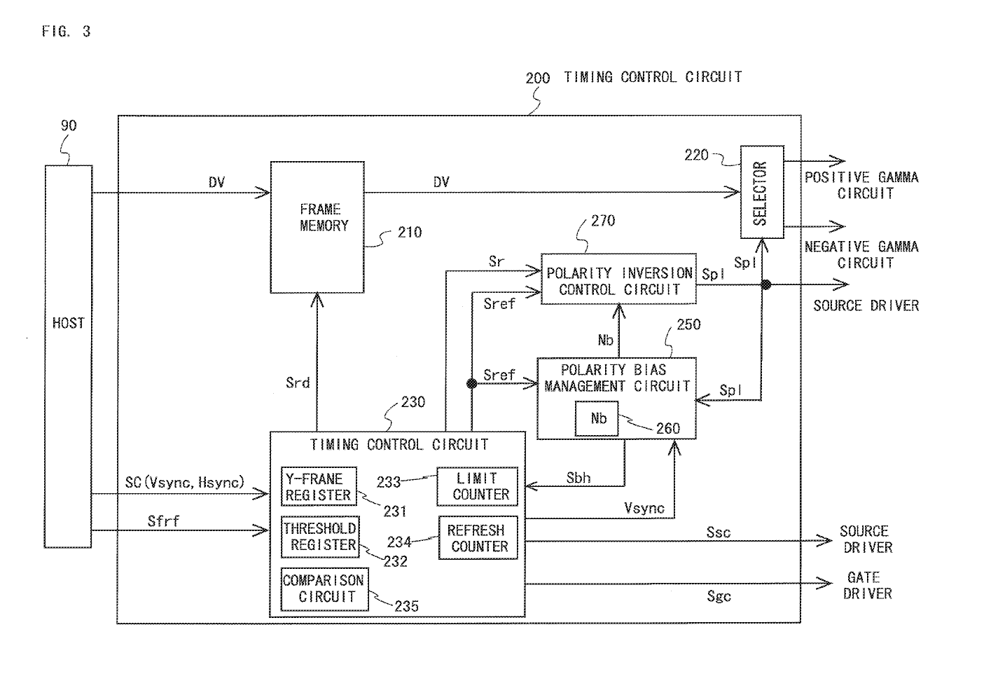

FIG. 3 is a block diagram illustrating the configuration of the display control portion 200 included in the liquid crystal display device 100 in the present embodiment. As shown in FIG. 3, the display control portion 200 includes frame memory 210, a timing control circuit 230, a polarity bias management circuit 250, a polarity inversion control circuit 270, and a selector 220. Data DAT transmitted from the host 90 includes image data DV, a control signals SC, such as a vertical synchronization signal Vsync or a horizontal synchronization signal Hsync, and a forced refresh signal Sfrf for forcing an image refresh, such as a RAM write signal Srw or an image update detection signal Svr. Such a refresh in accordance with the forced refresh signal Sfrf is referred to as a “forced refresh” or an “intended refresh”.

The frame memory 210 stores the image data DV transmitted from the host 90, frame by frame. The timing control circuit 230 provides a readout signal Srd to the frame memory 210 at the same time as outputting a refresh signal Sref, which will be described later, to the polarity bias management circuit 250 and the polarity inversion control circuit 270. As a result, the frame memory 210 outputs the stored image data DV to the source driver 310 via the selector 220 and the gamma portion 400. By providing the frame memory 210, the image data DV can be read out from the frame memory 210 at the time of updating the image displayed on the display portion 500, with the result that image updating can be performed readily. Note that during a pause frame period, the display portion 500 continues to display an image that is being displayed, and therefore, no readout signal Srd is provided to the frame memory 210. Moreover, in the present embodiment, the image data DV transmitted from the host 90 is described as being temporarily stored in the frame memory 210, but the image data DV may be provided directly from the host 90 to the selector 220 without being stored in the frame memory 210.

The timing control circuit 230 includes a Y-frame register 231 for memorizing a given period of time (referred to as a “Y-frame period”), a threshold register 232 for memorizing a threshold of an occurrence rate R for a limit refresh (unintended refresh), a limit counter 233 for counting the number of limit refreshes during the Y-frame period, a refresh counter 234 for counting the number of all refreshes during the Y-frame period, and a comparison circuit 235 for comparing the limit refresh occurrence rate R, which is obtained on the basis of the number of limit refreshes memorized by the limit counter 233 and the number of all refreshes memorized by the refresh counter 234, and the threshold memorized by the threshold register 232. Here, the “Y-frame period” (where “Y” is an arbitrary positive integer) memorized by the Y-frame register 231 represents a period extending back from a certain point in time, and the period to be extended back increases as the value of “Y” increases. Note that a specific example of the period specified by the Y-frame period in the present embodiment will be described later.

The timing control circuit 230 performs a forced refresh in accordance with the forced refresh signal Sfrf transmitted from the host 90, and also performs a refresh on the basis of a balance-limit-hit signal Sbh provided by the polarity bias management circuit 250 as will be described later. In the case of either refresh, the timing control circuit 230 outputs a refresh signal Sref to the polarity bias management circuit 250 and the polarity inversion control circuit 270. Moreover, upon each reception of the vertical synchronization signal Vsync from the host 90, the timing control circuit 230 outputs the received signal to the polarity bias management circuit 250. Note that in some cases, the refresh performed by the timing control circuit 230 on the basis of the balance-limit-hit signal Sbh received from the polarity bias management circuit 250 will also be referred to as the “limit refresh” or “unintended refresh”, and the balance-limit-hit signal Sbh will also be referred to as the “limit-hit signal”.

The polarity bias management circuit 250 includes a counter (referred to as a “balance counter”) 260 for holding a polarity bias value obtained on the basis of the vertical synchronization signal Vsync provided by the timing control circuit 230. The polarity bias value held in the balance counter 260 is represented by the symbol “Nb”. Upon each provision of the vertical synchronization signal Vsync from the timing control circuit 230, the polarity bias management circuit 250 adds or subtracts the number of receptions of the vertical synchronization signal Vsync to or from the polarity bias value Nb held in the balance counter 260, on the basis of a polarity signal Spl to be described later. Whether to add or subtract the number of receptions of the vertical synchronization signal Vsync is determined by the polarity signal Spl to be described later. More specifically, upon each provision of the polarity signal Spl from the polarity inversion control circuit 270, the polarity bias management circuit 250 increments or decrements the polarity bias value Nb stored in the balance counter 260 by “1”. As a result, the polarity bias value Nb becomes “positive”, “0”, or “negative”. Such a polarity bias value Nb has preset limits (upper and lower bounds), and when the polarity bias value Nb reaches either the upper or lower bound, the polarity bias management circuit 250 outputs the balance-limit-hit signal Sbh to the timing control circuit 230.

Upon each reception of the balance-limit-hit signal Sbh from the polarity bias management circuit 250, the timing control circuit 230 causes each of the limit counter 233 and the refresh counter 234 to count and memorize the number of receptions of the signal. Moreover, upon each reception of the forced refresh signal Sfrf from the host 90, the timing control circuit 230 causes the refresh counter 234 to count and memorize the number of receptions of the signal. That is, the refresh counter 234 counts and memorizes the total number of receptions of the balance-limit-hit signal Sbh and the forced refresh signal Sfrf.

Upon each reception of the balance-limit-hit signal Sbh from the polarity bias management circuit 250, the timing control circuit 230 reads out the number of receptions of the balance-limit-hit signal Sbh memorized by the limit counter 233 and the total number of receptions of the balance-limit-hit signal Sbh and the forced refresh signal Sfrf memorized by the refresh counter 234, and obtains an occurrence rate R by equation (1) as follows:

R=the number of receptions of the balance-limit-hit signal/(the number of receptions of the balance-limit-hit signal+the number of receptions of the forced refresh signal) (1)

Next, the occurrence rate R obtained by equation (1) and the threshold stored in the threshold register 232 are compared by the comparison circuit 235. As a result, when the occurrence rate R is determined to be less than the threshold, the timing control circuit 230 generates a refresh signal Sref to update an image being displayed on the display portion 500, and outputs the signal to the polarity inversion control circuit 270 and the polarity bias management circuit 250. On the other hand, when the occurrence rate R is determined to be greater than or equal to the threshold, the timing control circuit 230 generates and outputs a refresh signal Sref to the polarity inversion control circuit 270 and the polarity bias management circuit 250, and further, outputs an occurrence frequency signal Sr, which indicates the occurrence rate R, to the polarity inversion control circuit 270. Accordingly, the case where the occurrence rate R is determined to be less than the threshold and the case where the occurrence rate R is determined to be greater than or equal to the threshold will be described separately below. The following descriptions focus on one pixel forming portion 10 to which positive image data is inputted.

First, the case where the occurrence rate R is determined to be less than the threshold will be described. In this case, when a refresh signal Sref generated by the timing control circuit 230 for a limit refresh is provided to the polarity bias management circuit 250 and the polarity inversion control circuit 270, a polarity signal Spl for inverting a polarity with which an immediately preceding refresh has been performed, is generated and outputted to the selector 220, the source driver 310, and the polarity bias management circuit 250.

The selector 220 operates as below upon provision of the polarity signal Spl from the polarity inversion control circuit 270. Specifically, if the negative gamma circuit 420 was selected for the immediately preceding refresh, the positive gamma circuit 410 is selected for the current limit refresh, or if the positive gamma circuit 410 was selected for the immediately preceding refresh, the negative gamma circuit 420 is selected for the current refresh. As a result, regardless of the polarity bias value Nb, if a positive data voltage was generated for the previous refresh, a negative data voltage is generated for the current refresh, or if a negative data voltage was generated for the previous refresh, a positive data voltage is generated for the current refresh.

The source driver 310 operates as below upon provision of a polarity signal Spl from the polarity inversion control circuit 270. Specifically, if the selector 220 selects the positive gamma circuit 410, a positive data voltage is generated, and therefore, the source driver 310 selects the positive amplifier for amplifying the positive data voltage. If the negative gamma circuit 420 is selected, a negative data voltage is generated, and therefore, the source driver 310 selects the negative amplifier for amplifying the negative data voltage. Accordingly, the positive data voltage is amplified by the positive amplifier, or the negative data voltage is amplified by the negative amplifier, with the result that the data voltage applied to the liquid crystal layer of the pixel forming portion 10 has a polarity different from that of the data voltage applied during the immediately preceding refresh. Therefore, the data voltage applied to the liquid crystal layer of the pixel forming portion 10 is inverted in polarity relative to the data voltage applied for the previous refresh. In this manner, a refresh which involves polarity inversion is performed upon each provision of the balance-limit-hit signal Sbh or the forced refresh signal Sfrf to the timing control circuit 230.

In this case, when the polarity bias management circuit 250 is provided with a vertical synchronization signal Vsync by the timing control circuit 230 after the polarity signal Spl is provided by the polarity inversion control circuit 270, the polarity bias management circuit 250 operates as below. Specifically, in the case where the polarity bias value Nb was incremented by “1” for the immediately preceding refresh so as to approach “0”, when the vertical synchronization signal Vsync is provided by the timing control circuit 230 thereafter, the polarity bias value Nb is decremented by “1” so as to be away from “0”. Also, in the case where the polarity bias value Nb was decremented by “1” for the immediately preceding refresh so as to be away from “0”, when the vertical synchronization signal Vsync is provided by the timing control circuit 230 thereafter, the polarity bias value Nb is incremented by “1” so as to approach “0”. In this manner, the refresh is repeated with the polarity being inverted alternatingly, with the result that the polarity bias value repeats moving toward or alternatingly away from “0” in units of “1”.

Described next is the case where the occurrence rate R is determined to be greater than or equal to the threshold. In this case, when a balance-limit-hit signal Sbh is provided from the polarity bias management circuit 250 to the timing control circuit 230, the timing control circuit 230 generates and provides a refresh signal Sref to the polarity bias management circuit 250 and the polarity inversion control circuit 270, and also provides an occurrence frequency signal Sr to the polarity inversion control circuit 270.

Once the refresh signal Sref is provided to the polarity bias management circuit 250, the polarity bias management circuit 250 reads out the polarity bias value Nb stored in the balance counter 260, and provides the polarity bias value Nb to the polarity inversion control circuit 270. At this time, the polarity inversion control circuit 270 has already been provided with the occurrence frequency signal Sr, the polarity inversion control circuit 270 determines whether the polarity bias value Nb is “positive” or “negative”, and generates a polarity signal Spl so as to cause the polarity bias value to approach “0”. The polarity signal Spl thus generated is provided to the selector 220, the source driver 310, and the polarity bias management circuit 250.

Upon provision of the polarity signal Spl from the polarity inversion control circuit 270, the selector 220 selects the positive gamma circuit 410 or the negative gamma circuit 420 in accordance with the polarity signal Spl, such that the polarity bias value Nb approaches “0”. That is, when the polarity bias value Nb is “positive”, the negative gamma circuit 420 is selected, and when the polarity bias value Nb is “negative”, the positive gamma circuit 410 is selected. Accordingly, when the polarity bias value Nb is “positive”, a negative data voltage is generated, and when the polarity bias value Nb is “negative”, a positive data voltage is generated.

Upon provision of the polarity signal Spl from the polarity inversion control circuit 270, the source driver 310 selects the amplifier that matches the polarity of the data voltage. Accordingly, the positive data voltage is amplified by the positive amplifier, and the negative data voltage is amplified by the negative amplifier. As a result, when the polarity bias value Nb is “positive”, the negative data voltage is applied to the liquid crystal layer of the pixel forming portion 10, and when the polarity bias value Nb is “negative”, the positive data voltage is applied to the liquid crystal layer of the pixel forming portion 10.

When the polarity bias management circuit 250 is provided with a vertical synchronization signal Vsync by the timing control circuit 230 after the polarity signal Spl is provided by the polarity inversion control circuit 270, the polarity bias management circuit 250 increments or decrements the polarity bias value Nb held in the balance counter 260 by 1, such that the polarity bias value Nb approaches “0”. More specifically, when the polarity bias value Nb is “positive”, a decrement of 1 is made, and when the polarity bias value Nb is “negative”, an increment of “1” is made. As a result, when the next forced refresh signal Sfrf is provided by the host 90, the timing control circuit 230 generates and provides a refresh signal Sref to the polarity bias management circuit 250 and the polarity inversion control circuit 270.

In this manner, focusing on one pixel forming portion 10 to which positive image data is inputted, input image data is provided to the positive gamma circuit 410 so as to perform control such that the polarity bias value Nb increases, or input image data is provided to the negative gamma circuit 420 so as to perform control such that the polarity bias value Nb decreases. However, image data for one display screen includes not only pieces of positive image data but also the same number of pieces of negative image data. Accordingly, focusing on another pixel forming portion 10 to which negative image data for the same display screen is inputted, input image data is provided to the negative gamma circuit 420 so as to perform control such that the polarity bias value Nb increases, or input image data is provided to the positive gamma circuit 410 so as to perform control such that the polarity bias value Nb decreases. As a result, in either case, a polarity bias of the voltage applied to the liquid crystal layer can match the polarity bias value Nb managed by the polarity bias management circuit 250.

The refreshing has been described with respect to the limit refresh, which is performed when vertical synchronization signals Vsync provided from the host 90 to the polarity bias management circuit 250 are counted by the balance counter 260 and the count value exceeds a limit. However, in some cases, a forced refresh signal Sfrf for a forced refresh (intended refresh) is provided from the host 90 to the timing control circuit 230. In the case of such a forced refresh, the occurrence rate R that is greater than or equal to the threshold is not obtained by equation (1). Accordingly, as in the aforementioned case, the forced refresh is performed by inverting a polarity with which an immediately preceding refresh has been performed. Therefore, any description about the operation of the display control portion 200 for the forced refresh will be omitted.

Furthermore, high-frequency drive in which an image is updated every frame period corresponds to the case where the forced refresh is performed successively. Accordingly, any description of the operation of the display control portion 200 for high-frequency drive will also be omitted.

<1.3 Operation for Eliminating Polarity Bias>

The operation of the liquid crystal display device 100 according to the present embodiment for eliminating a polarity bias due to refreshes will be described in comparison to the polarity bias due to refreshes in a conventional liquid crystal display device. Accordingly, the polarity bias in a conventional liquid crystal display device will be described first.

<1.3.1 Conventional Liquid Crystal Display Device>

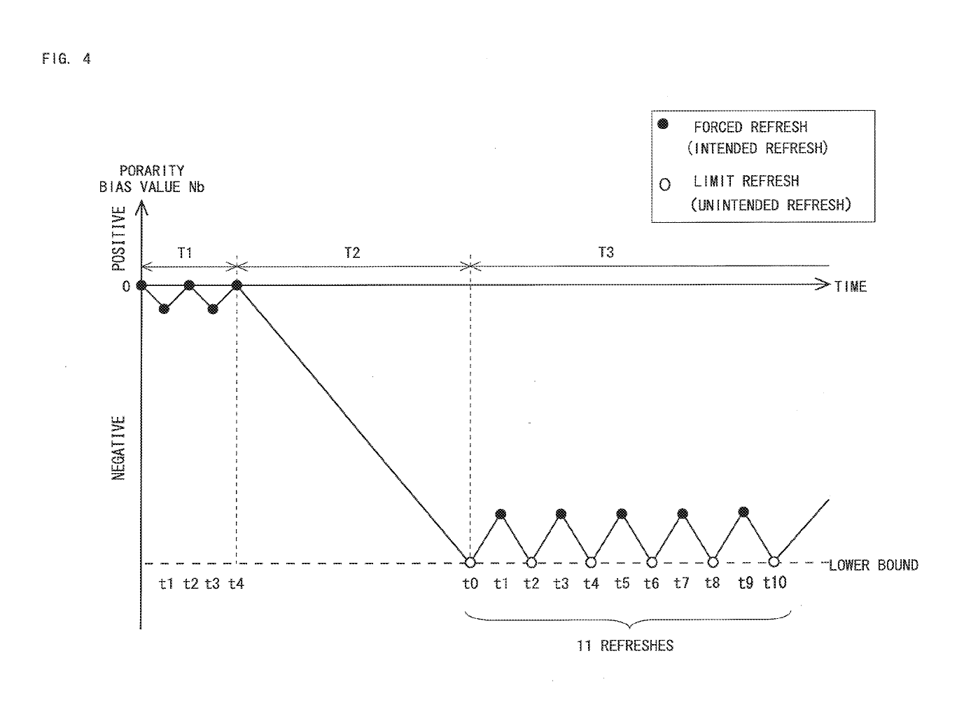

FIG. 4 is a diagram illustrating changes of the polarity bias value Nb for a conventional liquid crystal display device where refreshes are repeated. Note that in FIG. 4, forced refreshes are represented by black circles, and limit refreshes are represented by white circles.

Three periods T1 to T3 shown in FIG. 4 denote a high-frequency drive period T1, a pause frame period T2, and a limit refresh period T3, respectively. In the high-frequency drive period T1, polarity inversion occurs every frame period by means of high-frequency drive, so that the polarity bias value Nb is alternatingly incremented and decremented by “1” around “0”. In the pause frame period T2, the polarity bias value Nb continues to be more negative by means of pause drive.

Described next is the limit refresh period T3. When the polarity bias value Nb reaches a lower bound preset in the threshold register 232 of the polarity bias management circuit 250 at time t0, the polarity bias management circuit 250 provides a balance-limit-hit signal Sbh to the timing control circuit 230 in order to perform a limit refresh. Upon reception of the balance-limit-hit signal Sbh, the timing control circuit 230 generates and outputs a refresh signal Sref to the polarity inversion control circuit 270 and the polarity bias management circuit 250. Accordingly, a limit refresh is performed, with the result that data voltage held in each pixel forming portion 10 is rewritten such that the polarity thereof is inverted to positive.

At time t1, to perform a forced refresh in accordance with a forced refresh signal Sfrf provided by the host 90, the timing control circuit 230 generates and provides a refresh signal Sref to the polarity inversion control circuit 270 and the polarity bias management circuit 250. As a result, a data voltage whose polarity has been inverted to negative in conformity with image data DV is written to the pixel forming portion 10.

At time t2, the polarity bias value Nb reaches the preset lower bound, and therefore, the polarity bias management circuit 250 outputs a balance-limit-hit signal Sbh to the timing control circuit 230 in order to perform a limit refresh. The timing control circuit 230 generates and outputs a refresh signal Sref to the polarity inversion control circuit 270 and the polarity bias management circuit 250. Accordingly, a limit refresh is performed, with the result that the data voltage held in each pixel forming portion 10 is rewritten such that the polarity thereof is inverted to positive.

Thereafter, the forced refresh and the limit refresh repeatedly alternate with each other at times in a similar manner. As a result, for example, if the limit refresh is performed six times, the forced refresh is performed five times, so that the number of refreshes totals to 11.

<1.3.2 Liquid Crystal Display Device According to the Present Embodiment>

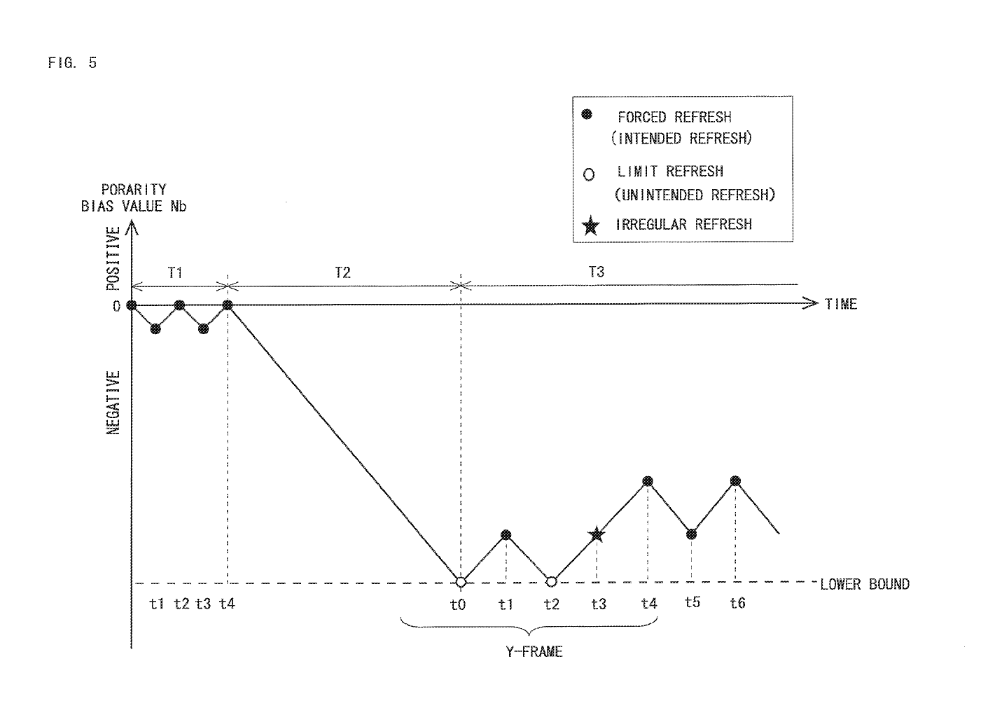

FIG. 5 is a diagram illustrating changes of the polarity bias value Nb for the liquid crystal display device 100 according to the present embodiment where a special refresh is performed. Note that in FIG. 5, forced refreshes (intended refreshes) and limit refreshes (unintended refreshes) are represented by black circles and white circles, respectively, as in FIG. 4, and a special refresh is represented by a star symbol. Moreover, three periods T1 to T3 denote a high-frequency drive period, a pause frame period, and a limit refresh period, respectively, and of the three periods, the high-frequency drive period T1 and the pause frame period T2 are the same as in the case of the conventional liquid crystal display device described above, therefore, any descriptions thereof will be omitted. Note that the special refresh will be described later.

Furthermore, in the present embodiment, the Y-frame period, which represents a given period of time, is set in the Y-frame register 231. The Y-frame period represents a period of time for which to determine whether to perform polarity inversion by a forced refresh, and the period extends back from the final determination point (in FIG. 5, time t4) to a certain point in time. In this case, the liquid crystal display device 100 determines whether to perform a special refresh, during the period defined by the Y-frame period.

At time t0 of the limit refresh period T3, the polarity bias value Nb reaches a preset lower bound, and the polarity bias management circuit 250 outputs a balance-limit-hit signal Sbh to the timing control circuit 230. Upon reception of the balance-limit-hit signal Sbh, the timing control circuit 230 generates and provides a refresh signal Sref to the polarity inversion control circuit 270 and the polarity bias management circuit 250. Accordingly, a limit refresh, which involves polarity inversion, is performed, with the result that a data voltage held in each pixel forming portion 10 is rewritten such that the polarity thereof is inverted to positive.

At this time, the timing control circuit 230 obtains an occurrence rate R of the limit refresh by assigning a count value in the limit counter 233, which counts the number of receptions of the balance-limit-hit signal Sbh, and a count value in the refresh counter 234, which counts the number of receptions of the forced refresh signal Sfrf and the balance-limit-hit signal Sbh, to equation (1), and the timing control circuit 230 compares the occurrence rate R and a threshold preset in the threshold register 232 (in the present embodiment, 60%). In the present embodiment, both the count value in the refresh counter 234 and the count value in the limit counter 233 are 1, and therefore, the occurrence rate R is 50% as obtained by equation (1). On the other hand, the threshold in the threshold register 232 is 60%. Accordingly, the occurrence rate R is determined to be less than the threshold, and the timing control circuit 230 simply outputs a refresh signal Sref but no occurrence frequency signal Sr.

Upon provision of the forced refresh signal Sfrf from the host 90 at time t1, the timing control circuit 230 generates a refresh signal Sref for a forced refresh on the basis of image data DV transmitted from the frame memory 210, and provides the generated signal to the polarity inversion control circuit 270 and the polarity bias management circuit 250. Accordingly, a forced refresh which involves polarity inversion is performed, with the result that a negative data voltage in conformity with the image data DV is written to the pixel forming portion 10. At this time, the polarity bias management circuit 250 decrements the polarity bias value Nb held in the balance counter 260 by “1” on the basis of a polarity signal Spl.

At time t2, the polarity bias value Nb reaches the preset lower bound, and then, the polarity bias management circuit 250 outputs a balance-limit-hit signal Sbh to the timing control circuit 230. Upon reception of the balance-limit-hit signal Sbh, the timing control circuit 230 generates and provides a refresh signal Sref to the polarity inversion control circuit 270 and the polarity bias management circuit 250. Accordingly, a limit refresh, which involves polarity inversion, is performed, with the result that the data voltage held in each pixel forming portion 10 is rewritten such that the polarity thereof is inverted to positive.

At this time, the timing control circuit 230 obtains an occurrence rate R of the limit refresh by assigning a count value in the limit counter 233, which counts the number of receptions of the balance-limit-hit signal Sbh, and a count value in the refresh counter 234, which counts the number of receptions of the forced refresh signal Sfrf and the balance-limit-hit signal Sbh, to equation (1), and then, the timing control circuit 230 compares the occurrence rate R and the preset threshold in the threshold register 232. In the present embodiment, the count values in the refresh counter 234 and the limit counter 233 are “3” and “2”, respectively, and therefore, the occurrence rate R is about 67% as obtained by equation (1). On the other hand, the threshold in the threshold register 232 is 60%. Therefore, the occurrence rate R is determined to be greater than or equal to the threshold, and the timing control circuit 230 generates a refresh signal Sref and an occurrence frequency signal Sr. Thereafter, the refresh signal Sref is outputted to the polarity bias management circuit 250 and the polarity inversion control circuit 270, and the occurrence frequency signal Sr is outputted to the polarity inversion control circuit 270.

Upon provision of the forced refresh signal Sfrf from the host 90 at time t3, the timing control circuit 230 generates a refresh signal Sref on the basis of image data DV transmitted from the frame memory 210, and provides the generated signal to the polarity inversion control circuit 270 and the polarity bias management circuit 250. In this case, on the basis of the occurrence frequency signal Sr provided by the timing control circuit 230 at time t2, the polarity inversion control circuit 270 performs a forced refresh which involves no polarity inversion. Such a forced refresh which involves no polarity inversion is referred to as a “special refresh”. The polarity inversion control circuit 270 generates a polarity signal Spl for a special refresh, and provides the generated signal to the selector 220, the source driver 310, and the polarity bias management circuit 250. Since the limit refresh at time t2 is a positive refresh, the selector 220 selects the positive gamma circuit 410 in accordance with the polarity signal Spl, and the source driver 310 amplifies the data voltage by means of the positive amplifier. As a result, at time t3, as at time t2, a positive data voltage in conformity with the image data DV is written to the pixel forming portion 10. Moreover, the polarity bias management circuit 250 increments the polarity bias value Nb by “1” on the basis of the polarity signal Spl.

Upon provision of a forced refresh signal Sfrf from the host 90 at time t4, the timing control circuit 230 generates a refresh signal Sref on the basis of image data DV transmitted from the frame memory 210, and provides the generated signal to the polarity inversion control circuit 270 and the polarity bias management circuit 250. Accordingly, a forced refresh which involves polarity inversion is performed, with the result that a negative data voltage in conformity with the image data DV is written to the pixel forming portion 10. At this time, the polarity bias management circuit 250 decrements the polarity bias value Nb held in the balance counter 260 by “1” on the basis of the polarity signal Spl.

Upon provision of a forced refresh signal Sfrf from the host 90 at time t5, the timing control circuit 230 generates a refresh signal Sref on the basis of image data DV transmitted from the frame memory 210, and provides the generated signal to the polarity inversion control circuit 270 and the polarity bias management circuit 250. Accordingly, a forced refresh which involves polarity inversion is performed, with the result that a positive data voltage in conformity with the image data DV is written to the pixel forming portion 10, and at the same time as the writing, the polarity bias value Nb held in the balance counter 260 is incremented by “1”. At time t6, similarly, a forced refresh which involves polarity inversion is performed, with the result that a data voltage in conformity with negative image data DV is written to the pixel forming portion 10, and at the same time as the writing, the polarity bias value Nb held in the balance counter 260 is decremented by “1”. In this manner, the special refresh is performed at time t3, therefore, from time t4 onward, no limit refresh is performed, and only forced refreshes are performed.

<1.4 Power Consumption>

Power consumed by refreshes in the liquid crystal display device 100 according to the present embodiment will be described in comparison to power consumed by refreshes in a conventional liquid crystal display device. Accordingly, power consumed by refreshes in a conventional liquid crystal display device will be described first.

<1.4.1 Conventional Liquid Crystal Display Device>

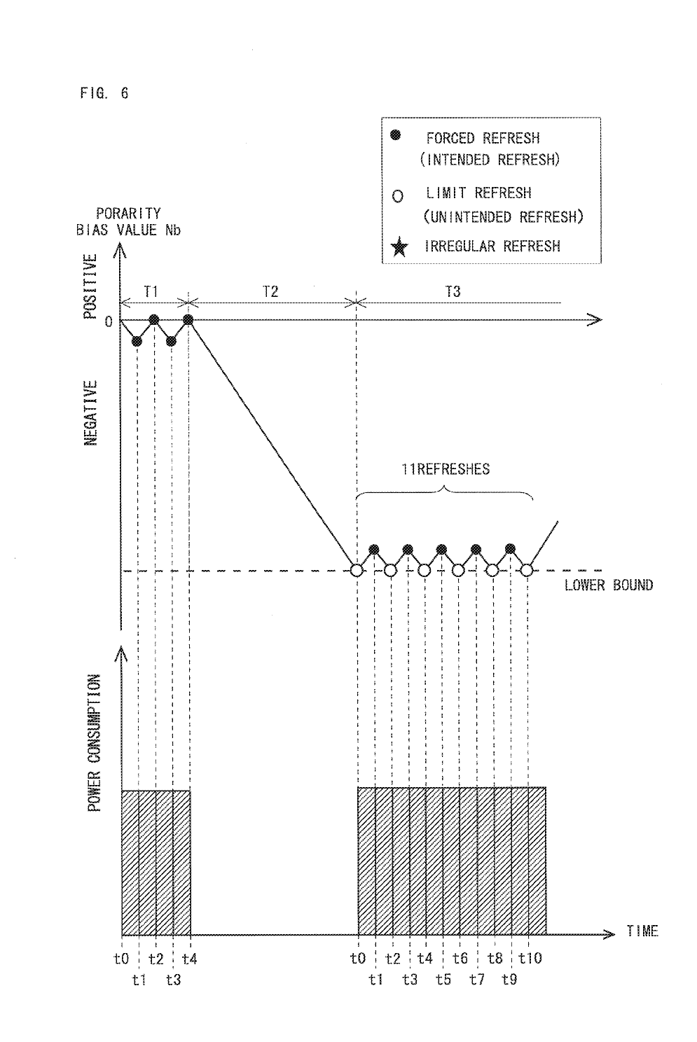

FIG. 6 is a diagram illustrating power consumption by a conventional liquid crystal display device. As shown in FIG. 6, four forced refreshes are performed in short cycles from time t1 to time t4 during a high-frequency drive period T1, and power is thereby consumed at each time. During the following pause frame period T2, pause drive is performed, and therefore, no power is consumed for a refresh.

During a limit refresh period T3, the forced refresh and the limit refresh alternate with each other. For example, in the case shown in FIG. 6, six limit refreshes are performed while five forced refreshes are performed, and therefore, the number of refreshes performed totals to 11. Accordingly, power is consumed in each drive period from the initial forced refresh at time t0 to the last forced refresh at time t10. Therefore, the total power consumption from time t0 to time t10 during the limit refresh period T3 is significant.

<1.4.2 Liquid Crystal Display Device According to the Present Embodiment>

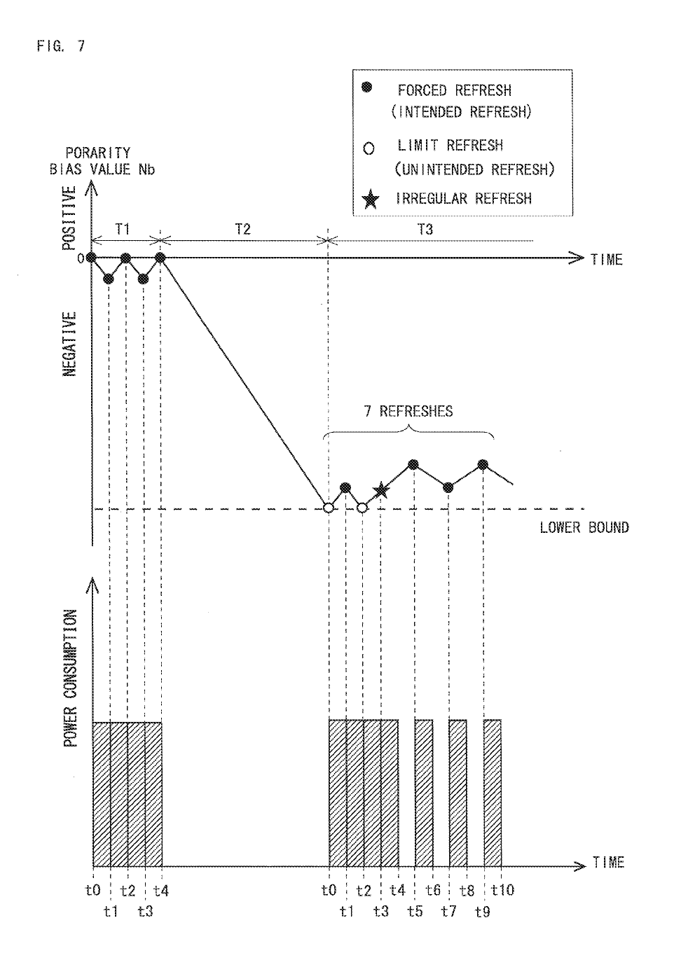

FIG. 7 is a diagram illustrating power consumption by the liquid crystal display device 100 according to the present embodiment. A high-frequency drive period T1 shown in FIG. 7 represents a period extending back from the final determination point (in FIG. 7, time t4) to a certain point in time. In this case, the liquid crystal display device 100 determines whether to perform a special refresh, during a period of time defined by the Y-frame period. Power consumption during a pause frame period T2 is the same as in the case shown in FIG. 6, and therefore, any description thereof will be omitted.

Next, from time t0 to time t3 during a limit refresh period T3, the limit refresh alternates with the forced refresh in short cycles of drive period, starting with a limit refresh at time t0 and ending with a special refresh at time t3, and therefore, power is consumed by a refresh in each drive period, as in the case shown in FIG. 6.

However, a special refresh, which involves no polarity inversion, is performed at time t3, so that the polarity bias value Nb does not reach a lower bound from time t4 onward, and therefore, no limit refresh is performed thereafter. Accordingly, power to perform a limit refresh is not required. Moreover, power to perform refreshes is still required for forced refreshes from time t4 onward, but the cycle of inversion is longer, and power to perform a refresh is not required in the latter portion of each cycle of inversion. Thus, the liquid crystal display device 100 renders it possible to reduce power consumption during the limit refresh period T3 when compared to conventional liquid crystal display devices.

<1.5 Effects>

In the liquid crystal display device 100 according to the present embodiment, for example, when five forced refreshes are performed, a special refresh, which involves no polarity inversion, is performed, provided that the occurrence rate R of the limit refresh during a Y-frame period, which is set to be a given period of time, is greater than or equal to a predetermined threshold. As a result, the polarity bias value Nb moves away from the lower bound or the limit, and never reaches the lower bound.

Accordingly, it is unnecessary to perform a further limit refresh, so that the number of limit refreshes can be diminished. Thus, the total power consumption by refreshes during the limit refresh period T3 can be lower than is conventionally required.

Furthermore, the liquid crystal display device 100 determines whether to perform a special refresh using the Y-frame register 231, the threshold register 232, the limit counter 233, the refresh counter 234, and the comparison circuit 235, and therefore, an erroneous determination which causes polarity inversion, even though polarity inversion is unnecessary, is less likely to occur. Thus, it is possible to inhibit power consumption from increasing due to another limit refresh being performed.

<1.6 Variants>

In the first embodiment, the threshold set in the threshold register 232 is 60%, but the threshold may be higher or lower. Increasing the threshold can delay the time to perform the ispecial refresh, whereas decreasing the threshold can expedite the time to perform the special refresh.

Furthermore, in the first embodiment, the occurrence rate R is obtained by equation (1). However, the occurrence rate R may be obtained, for example, by equation (2) below or by another method.

R=the number of receptions of the balance-limit-hit signal/the number of receptions of the forced refresh signal (2)

Note that in the above variant, unlike in the first embodiment, the refresh counter 234 counts the number of receptions of the forced refresh signal.

### 2. Second Embodiment

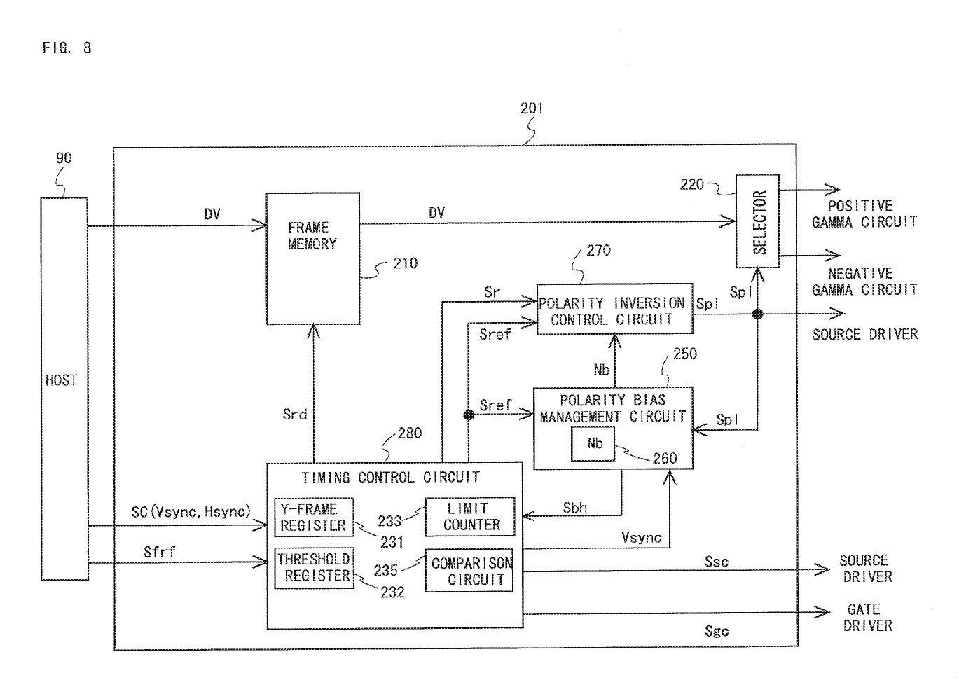

The configuration of a liquid crystal display device according to a second embodiment is the same as that of the liquid crystal display device 100 according to the first embodiment shown in FIG. 2, and therefore, any block diagram illustrating the configuration and any description thereof will be omitted. FIG. 8 is a block diagram illustrating the configuration of a display control portion 201 included in the liquid crystal display device according to the second embodiment of the present invention. As shown in FIG. 8, the display control portion 201 in the present embodiment has almost the same configuration as the display control portion 200 in the first embodiment shown in FIG. 3, but is different in the configuration of the timing control circuit 280. Accordingly, the configuration of the timing control circuit 280 will be described while any descriptions of the configurations of the other elements will be omitted.

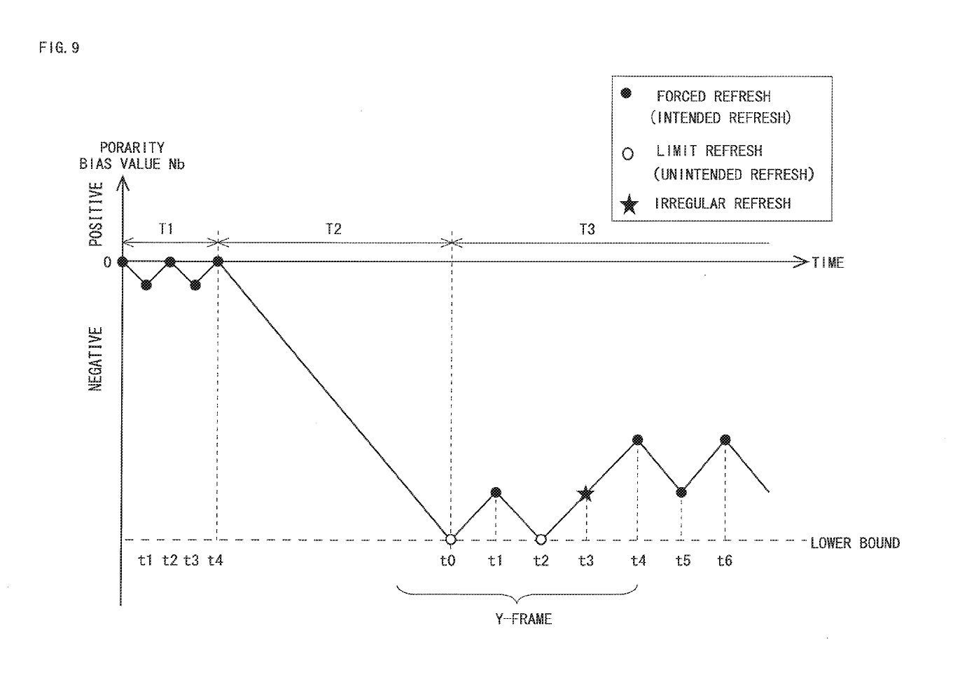

In the present embodiment, whether to perform a special refresh as a forced refresh is determined by the number of occurrences of the limit refresh, rather than by the occurrence rate R of the limit refresh, as will be described later. Accordingly, the timing control circuit 280 does not need the refresh counter 234 included in the timing control circuit 230 shown in FIG. 3. Moreover, the threshold register 232 has memorized therein a threshold of the number of occurrences, rather than a threshold of the occurrence rate R. Therefore, as shown in FIG. 9, for example, the Y-frame period represents a period extending back from time t4 to a point in time within a pause frame period T2. In this case, the liquid crystal display device 100 determines whether to perform a special refresh, during the period defined by the Y-frame period. Note that the threshold register 232 in the present embodiment is assumed to have memorized, for example, “2” therein as the threshold of the number of occurrences, but the special refresh can be performed during the period defined by the Y-frame period if the memorized number of occurrences is from 1 to 5.

<2.1 Operation of Eliminating the Polarity Bias>

FIG. 9 is a diagram illustrating changes of the polarity bias value Nb for the liquid crystal display device 100 according to the present embodiment where a special refresh is performed. In FIG. 9, as in the case shown in FIG. 5, periods T1 to T3 represent the high-frequency drive period, the pause frame period, and the limit refresh period, respectively, and also, the Y-frame period is set.

The high-frequency drive period T1 and the pause frame period T2 are the same as those in the first embodiment, and therefore, any descriptions thereof will be omitted. The limit refresh period T3 will now be described. At time t0, the polarity bias value Nb reaches a lower bound, and the timing control circuit 280 receives a balance-limit-hit signal Sbh from the polarity bias management circuit 250, and then generates and provides a refresh signal Sref to the polarity inversion control circuit 270 and the polarity bias management circuit 250. At this time, the timing control circuit 280 compares a count value in the limit counter 233, which counts the number of receptions of the balance-limit-hit signal Sbh, i.e., the number of occurrences of the limit refresh, and a threshold of the number of occurrences of the limit refresh, which is preset in the threshold register 232. In this case, the number of occurrences of the limit refresh is “1”, and the threshold of the number of occurrences is “2”. Accordingly, the timing control circuit 280 compares the number of occurrences of the limit refresh and the threshold by means of the comparison circuit 235, determines that the number of occurrences of the limit refresh is less than the threshold, and simply outputs a refresh signal Sref. Accordingly, a limit refresh, which involves polarity inversion, is performed, with the result that a data voltage held in each pixel forming portion 10 is rewritten such that the polarity thereof is inverted to positive.

Upon provision of a forced refresh signal Sfrf from the host 90 at time t1, a forced refresh is performed on the basis of image data DV transmitted from the frame memory 210. Accordingly, at time t1, the forced refresh causes polarity inversion, with the result that a negative data voltage in conformity with the image data DV is written to the pixel forming portion 10. At this time, the polarity bias management circuit 250 increments the polarity bias value Nb held in the balance counter 260 by “1” on the basis of a polarity signal Spl generated at time to.

When the polarity bias value Nb reaches a preset lower bound at time t2, the polarity bias management circuit 250 outputs a balance-limit-hit signal Sbh to the timing control circuit 280. Upon reception of the balance-limit-hit signal Sbh, the timing control circuit 280 generates and provides a refresh signal Sref to the polarity inversion control circuit 270 and the polarity bias management circuit 250.

At this time, the timing control circuit 280 compares a count value in the limit counter 233, which counts the number of receptions of the balance-limit-hit signal Sbh, and a threshold of the number preset in the threshold register 232. In the present embodiment, the count value of the limit counter 233 is “2”, and the threshold of the number of occurrences in the threshold register 232 is “2”. Accordingly, the count value in the limit counter 233 is determined to be greater than or equal to the threshold, and therefore, the timing control circuit 230 generates a refresh signal Sref and an occurrence frequency signal Sr. Thereafter, the refresh signal Sref is outputted to the polarity bias management circuit 250 and the polarity inversion control circuit 270, and the occurrence frequency signal Sr is outputted to the polarity inversion control circuit 270. Accordingly, a limit refresh, which involves polarity inversion, is performed, with the result that a data voltage held in each pixel forming portion 10 is rewritten such that the polarity thereof is inverted to positive. Moreover, the polarity bias management circuit 250 decrements the polarity bias value Nb held in the balance counter 260 by “1” on the basis of a polarity signal Spl generated at time t1.

Upon provision of a forced refresh signal Sfrf from the host 90 at time t3, a forced refresh is performed on the basis of image data DV transmitted from the frame memory 210. In this case, the occurrence frequency signal Sr is provided to the polarity inversion control circuit 270 at time t2 as a result of the number of occurrences of the limit refresh being determined to be greater than or equal to the threshold. Accordingly, at time t3, unlike at time t1, the polarity of a data voltage held in each pixel forming portion is not inverted, and a special refresh for positive polarity is performed, with the result that a positive data voltage in conformity with the image data DV is written to the pixel forming portion 10.

Since the special refresh for positive polarity is performed at time t3, the polarity bias value Nb is incremented by “1” at time t4. As a result, the polarity bias value Nb approaches “0” away from the lower bound. Accordingly, even if forced refreshes for negative and positive polarities are performed alternatingly from time t4 to time t6, the polarity bias value Nb does not reach the lower bound. Therefore, forced refreshes for negative and positive polarities are performed alternatingly from time t4 to time t6, so that negative and positive data voltages are written alternatingly to the pixel forming portion 10 in accordance with the image data DV.

<2.2 Power Consumption>

In the present embodiment, as in the first embodiment, when a special refresh is performed at time t3 during the limit refresh period T3, the polarity bias value Nb approaches “0”. Accordingly, no limit refresh is performed from time t4 onward, resulting in a longer inversion cycle of the forced refresh. Therefore, as in the first embodiment shown in FIG. 7, power to perform a limit refresh is not required in the latter portion of the inversion cycle of the forced refresh from time t3 to time t6. Thus, the liquid crystal display device according to the present embodiment also renders it possible to reduce power consumption when compared to conventional liquid crystal display devices.

<2.3 Effects>

The liquid crystal display device according to the present embodiment renders it possible to achieve effects similar to those achieved by the first embodiment. Moreover, to determine whether to perform a special refresh, the number of receptions of the limit refresh signal is directly compared with the threshold thereof, and therefore, unlike in the first embodiment, the refresh counter 234 is unnecessary. Thus, the circuit configuration of the timing control circuit 280 can be simplified, resulting in a reduced cost of producing the liquid crystal display device.

<2.4 Variants>

In the above embodiment, when the polarity bias value reaches the lower bound for the second time at time t2, the occurrence frequency signal Sr is generated and provided to the polarity inversion control circuit 270, thereby performing a limit refresh, and then at time t3, a special refresh, which involves no polarity inversion, is performed as a forced refresh. However, this is illustrative, and by changing the threshold of the number of occurrences of the limit refresh, which is set in the threshold register 232, the threshold of the number of occurrence of the limit refresh, which is used to determine whether to perform a special refresh, can be changed to an arbitrary value. In this case, it is necessary to adjust the period that is set as the Y-frame period in accordance with the threshold of the number of occurrence.

### 3. Third Embodiment

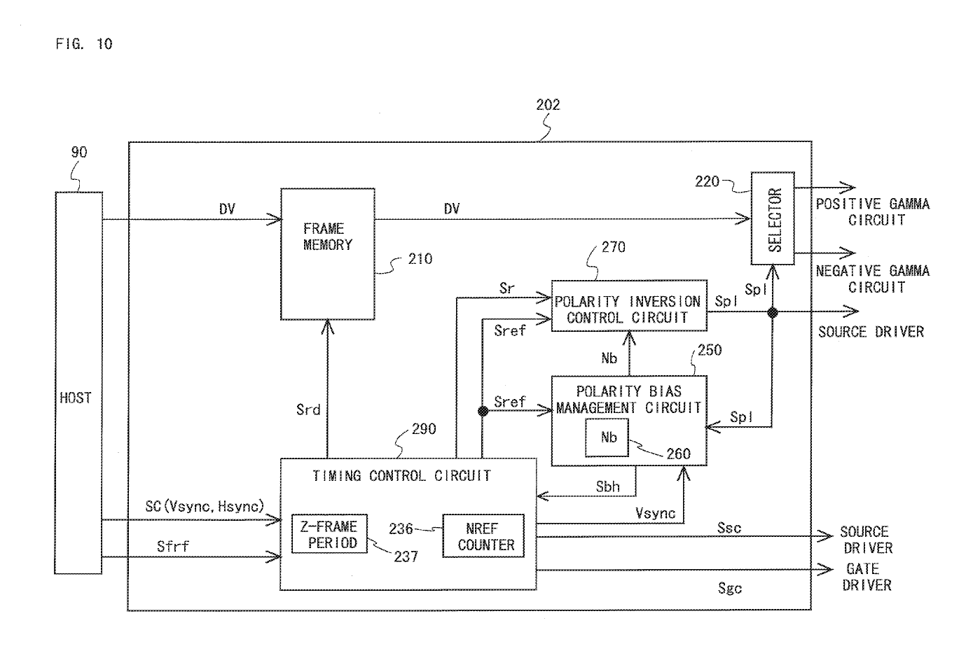

The configuration of a liquid crystal display device according to a third embodiment is the same as that of the liquid crystal display device 100 according to the first embodiment shown in FIG. 2, and therefore, any block diagram illustrating the configuration and any description thereof will be omitted. FIG. 10 is a block diagram illustrating the configuration of a display control portion 202 included in the liquid crystal display device according to the third embodiment of the present invention. As shown in FIG. 10, the display control portion 202 in the present embodiment has almost the same configuration as the display control portion 200 in the first embodiment shown in FIG. 3, but is different in the configuration of a timing control circuit 290. Accordingly, the configuration of the timing control circuit 290 will be described while any descriptions of the configurations of the other elements will be omitted.

In the present embodiment, whether to perform a special refresh is determined depending on whether the polarity bias value Nb reaches a lower bound within a predetermined period of time (referred to as a “Z-frame period”), as will be described later. The timing control circuit 290 includes a Z-frame register 237 for memorizing the Z-frame period and an NREF counter 236 for counting the number of frames during which no refresh is performed. When the number of frames during which no refresh is performed, counted by the NREF counter 236, reaches a prescribed value, the liquid crystal display device performs a refresh (referred to as a “regular refresh”) even when no image data DV is provided by the host 90. Note that other registers, counters, etc., provided in the timing control circuits 230 and 280 in the first and second embodiments are not provided.

Next, the Z-frame period will be described. The “Z” of the Z-frame period, as with the “Y” of the Y-frame period, represents a positive integer, the period varies depending on the value of Z, and the greater the value of Z, the longer the period. The Y-frame period represents a period extending back from a given point in time, but the Z-frame period represents a period extending forward from the time immediately after the initial limit refresh. The time of the initial limit refresh is not included in the Z-frame period, and when a limit refresh is performed, even if only once, during the Z-frame period, a special refresh is performed, and therefore, the threshold register 232, the limit counter 233, the refresh counter 234, and the comparison circuit 235 included in the timing control circuits 230 and 280 in the first and second embodiments are not included.

<3.1 Operation of Eliminating the Polarity Bias>

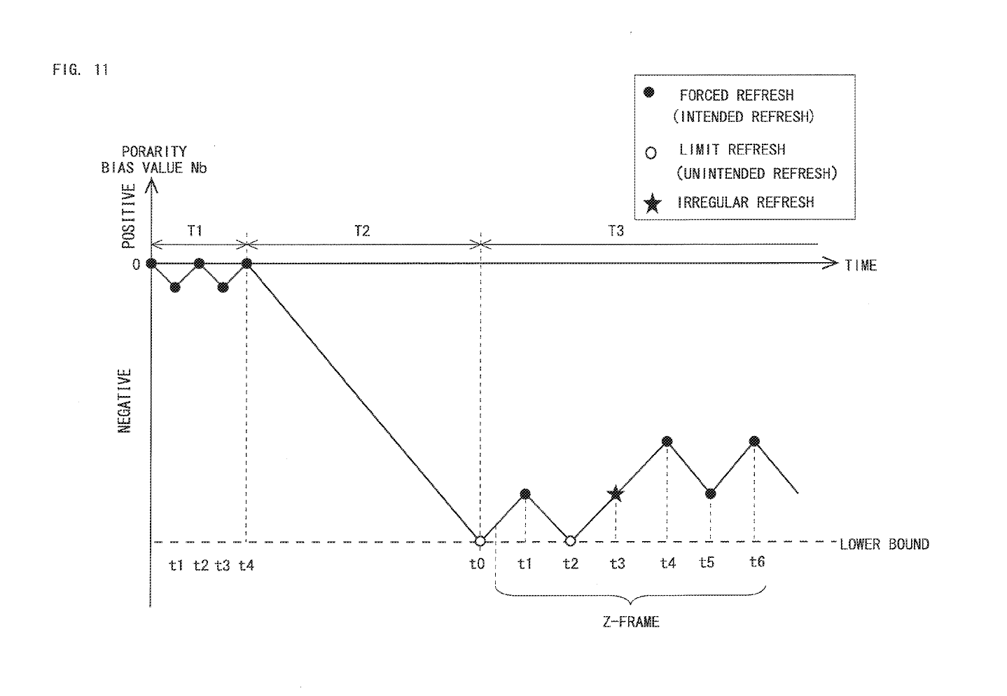

FIG. 11 is a diagram illustrating changes of the polarity bias value Nb for the liquid crystal display device according to the present embodiment where a special refresh is performed. In FIG. 11, as in the case shown in FIG. 5, three periods T1 to T3 denote the high-frequency drive period, the pause frame period, and the limit refresh period.

As shown in FIG. 11, at time t0, the polarity bias value Nb reaches a lower bound, so that the timing control circuit 290 generates and provides a refresh signal to the polarity inversion control circuit 270 and the polarity bias management circuit 250. Accordingly, a limit refresh, which involves polarity inversion, is performed, with the result that a data voltage held in each pixel forming portion 10 is rewritten such that the polarity thereof is inverted to positive. Note that in the present embodiment, the initial limit refresh is performed at time t0, and therefore, time t0 is not included in the Z-frame period, which is set to be a period extending forward from a point in time immediately after time t0 to time t6.

Upon provision of a forced refresh signal Sfrf from the host 90 at time t1, a forced refresh is performed on the basis of image data DV transmitted from the frame memory 210. Moreover, the limit refresh at time t0 is not a refresh during the Z-frame period. Accordingly, the forced refresh performed at time t1 involves polarity inversion, so that a data voltage in conformity with negative image data DV is written to the pixel forming portion 10. Moreover, no occurrence frequency signal Sr is provided to the polarity inversion control circuit 270 at time t0, and therefore, the polarity bias value Nb in the balance counter 260 is decremented by “1” so as to move away from “0”.

When the polarity bias value Nb reaches the preset lower bound for the first time at time t2, the polarity bias management circuit 250 outputs a balance-limit-hit signal Sbh to the timing control circuit 280. Upon reception of the balance-limit-hit signal Sbh, the timing control circuit 280 generates and provides a refresh signal Sref to the polarity inversion control circuit 270 and the polarity bias management circuit 250, and also outputs an occurrence frequency signal Sr to the polarity inversion control circuit 270. Accordingly, a limit refresh, which involves polarity inversion, is performed, with the result that a data voltage held in each pixel forming portion 10 is rewritten such that the polarity thereof is inverted to positive. Moreover, since the forced refresh is performed at time t1, polarity inversion occurs, and the polarity bias value Nb in the balance counter 260 is incremented by “1” so as to approach “0”.

Upon provision of a forced refresh signal Sfrf from the host 90 at time t3, a special refresh is performed on the basis of image data DV transmitted from the frame memory 210. In this case, the occurrence frequency signal Sr generated by the timing control circuit 290 at time t2 has already been provided to the polarity inversion control circuit 270. Accordingly, at time t3, unlike at time t1, the polarity inversion control circuit 270 generates a polarity signal Spl on the basis of the occurrence frequency signal Sr, and outputs the generated signal to the selector, the source driver, and the polarity bias management circuit 250. Therefore, the polarity of a positive data voltage held in each pixel forming portion 10 is not inverted, and a special refresh, which involves no polarity inversion, is performed, with the result that a data voltage in conformity with the positive image data DV is written to the pixel forming portion 10. Moreover, the polarity bias value Nb in the balance counter 260 is incremented by “1” so as to approach “0”.

Since the special refresh for positive polarity is performed without causing polarity inversion at time t3, the polarity bias value Nb does not reach the lower bound even if forced refreshes for negative and positive polarities are performed alternatingly from time t4 to time t6. Thus, from time t4 to time t6, the polarity of the data voltage held in each pixel forming portion 10 is inverted alternatingly, and forced refreshes for negative and positive polarities are performed alternatingly.

<3.2 Power Consumption>

In the present embodiment, as in the first embodiment, when a special refresh is performed at time t3 during the limit refresh period T3, no limit refresh is performed thereafter, resulting in a longer cycle of the forced refresh. Accordingly, as in the first embodiment, power to perform a refresh is not required in the latter portion of each inversion cycle of the forced refresh. Thus, the liquid crystal display device 100 renders it possible to reduce power consumption when compared to conventional liquid crystal display devices.

<3.3 Effects>

The liquid crystal display device according to the present embodiment renders it possible to achieve effects similar to those achieved by the first embodiment. Moreover, the Y-frame register 231, the threshold register 232, the limit counter 233, the refresh counter 234, and the comparison circuit 235 provided in the timing control circuit 230 in the first embodiment are not required in determining whether to perform a special refresh, and therefore, erroneous determinations might be made to perform polarity inversion by mistake even when inversion should not be performed, and vice versa. This might increase the number of limit refreshes, resulting in increased power consumption, but the configuration of the timing control circuit 230 can be simplified, whereby the cost of producing the liquid crystal display device can be kept low.

<3.3 Variants>

In the above embodiment, when the polarity bias value Nb reaches the lower bound for the first time during the Z-frame period, the timing control circuit 290 generates and outputs the occurrence frequency signal Sr to the polarity inversion control circuit 270 in order to perform the special refresh, which involves no polarity inversion, as the next forced refresh. However, this is illustrative, and the special refresh may be performed, for example, when the polarity bias value Nb reaches the lower bound for the second or third times or more during the Z-frame period. In this case, it is necessary to additionally provide the timing control circuit 290 with a limit counter for counting the number of limit refreshes.

### 4. Variant Common Among the Embodiments

In each of the embodiments, the limit that the polarity bias value Nb reaches during the limit refresh period T3 has been described as being the lower bound. However, the present invention can be similarly applied even when the limit that the polarity bias value Nb reaches is the upper bound.

### 5. TFT in the Pixel Forming Portion

Hereinafter, the TFT included in the pixel forming portion of the liquid crystal display device according to each of the embodiments of the present invention will be described. The TFT 11 included in the pixel forming portion 10, as shown in FIG. 2, may be a channel-etched or an etch-stop TFT with an oxide semiconductor layer. The oxide semiconductor layer may be formed with an indium gallium zinc oxide or a crystalline oxide semiconductor, or may have a stack structure. By using the TFT with an oxide semiconductor layer, it becomes possible to significantly cut down the number of times of driving the liquid crystal panel while maintaining display quality, and also significantly diminish power consumption by the liquid crystal display device.

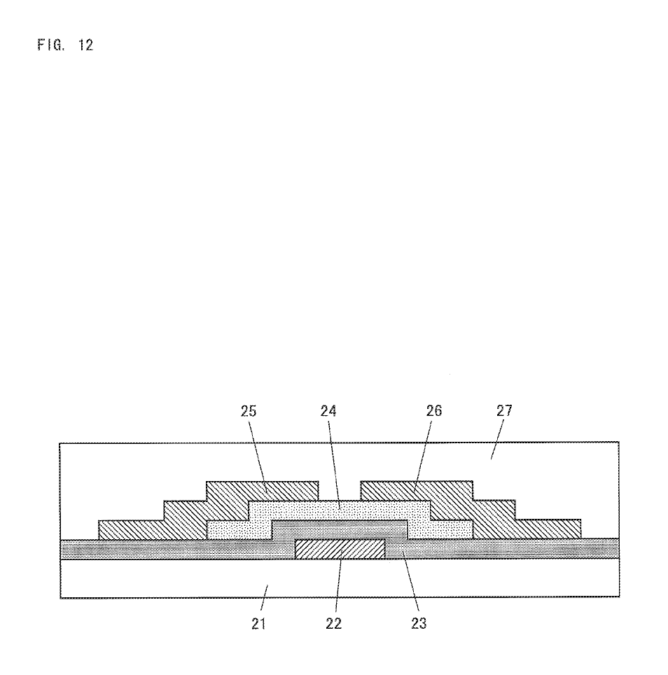

FIG. 12 is a diagram illustrating the structure of a channel-etched TFT. As shown in FIG. 12, the channel-etched TFT is structured such that a gate electrode 22, a gate insulating film 23, an oxide semiconductor layer 24, a source electrode 25, and a drain electrode 26 are stacked on a substrate 21, and a protective film 27 is formed on top. A portion of the oxide semiconductor layer 24 that lies above the gate electrode 22 functions as a channel region. The channel-etched TFT has no etch-stop layer formed on the channel region, and the source electrode 25 and the drain electrode 26 are disposed such that bottom surfaces of channel-side ends contact a top surface of the oxide semiconductor layer 24. The channel-etched TFT is completed, for example, by forming a conductive film serving as a source/drain electrode on the oxide semiconductor layer 24 and performing the process of separating the source and the drain. In some cases, the surface of the channel region is etched during the source-drain separating process.

The etch-stop TFT (not shown) has an etch-stop layer formed on a channel region. Source and drain electrodes are such that bottom surfaces of channel-side ends are positioned, for example, on the etch-stop layer. The etch-stop TFT is completed, for example, by forming the etch-stop layer so as to cover a portion of an oxide semiconductor layer that serves as the channel region, thereafter forming a conductive film that serves as a source/drain electrode on the oxide semiconductor layer and the etch-stop layer, and performing the process of separating the source and the drain.

The oxide semiconductor included in the oxide semiconductor layer of the TFT may be an amorphous oxide semiconductor or a crystalline oxide semiconductor with a crystalline portion. As the crystalline oxide semiconductor, for example, a polycrystalline oxide semiconductor, a microcrystalline oxide semiconductor, or a crystalline oxide semiconductor with the c-axis oriented approximately vertical to the surface of the layer can be used.

The oxide semiconductor layer of the TFT may have a stack structure of two or more layers. In such a case, the oxide semiconductor layer may include both a non-crystalline oxide semiconductor layer and a crystalline oxide semiconductor layer, a plurality of crystalline oxide semiconductor layers with different crystal structures, or a plurality of non-crystalline oxide semiconductor layers. In the case where the oxide semiconductor layer has a two-layer structure including top and bottom layers, the oxide semiconductor contained in the top layer preferably has a larger energy gap than the oxide semiconductor contained in the bottom layer. However, in the case where the difference in energy gap between the two layers is relatively small, the bottom-layer oxide semiconductor may have a larger energy gap than the top-layer oxide semiconductor.

The materials, the structures, and the forming methods of the non-crystalline oxide semiconductor and the crystalline oxide semiconductors, along with the configurations of the oxide semiconductor layers with stack structures, etc., are described in, for example, Japanese Laid-Open Patent Publication No. 2014-7399. The disclosure of Japanese Laid-Open Patent Publication No. 2014-7399 is incorporated herein by reference in its entirety.

The oxide semiconductor layer may contain, for example, at least one of the following metallic elements: In, Ga, and Zn. The oxide semiconductor layer includes, for example, an In—Ga—Zn—O based semiconductor (e.g., indium gallium zinc oxide). The In—Ga—Zn—O based semiconductor is a ternary oxide composed of In (indium), Ga (gallium), and Zn (zinc). The ratio (composition ratio) of In, Ga, and Zn is not specifically limited, and may be such that, for example, In:Ga:Zn=2:2:1, In:Ga:Zn=1:1:1, or In:Ga:Zn=1:1:2. The oxide semiconductor layer is formed using an oxide semiconductor film containing an In—Ga—Zn—O based semiconductor. Note that the channel-etched TFT with an active layer which contains an oxide semiconductor (OS), such as an In—Ga—Zn—O based semiconductor, is also referred to as the “CE-OS-TFT”.

The In—Ga—Zn—O based semiconductor may be amorphous or crystalline. The crystalline In—Ga—Zn—O based semiconductor preferably has the c-axis oriented approximately vertical to the layer surface.

It should be noted that the crystal structure of the crystalline In—Ga—Zn—O based semiconductor is disclosed, for example, in Japanese Laid-Open Patent Publication No. 2014-7399, mentioned earlier, as well as in Japanese Laid-Open Patent Publication Nos. 2012-134475 and 2014-209727. The disclosures of Japanese Laid-Open Patent Publication Nos. 2012-134475 and 2014-209727 are incorporated herein by reference in their entirety. TFTs with In—Ga—Zn—O based semiconductor layers offer high mobility (more than 20 times as high as a-Si TFTs) and low leakage current (less than 1/100 of that of a-Si TFTs). Accordingly, TFTs with In—Ga—Zn—O based semiconductor layers are preferably used as drive TFTs (e.g., the TFTs being included in driver circuits provided around a display area, which includes a plurality of pixel circuits, on the same substrate), and also as pixel TFTs (the TFTs being provided in pixel circuits).

Instead of containing the In—Ga—Zn—O based semiconductor, the oxide semiconductor layer may contain another oxide semiconductor. The oxide semiconductor layer may contain, for example, an In—Sn—Zn—O based semiconductor (e.g., In₂O₃—SnO₂—ZnO or InSnZnO). The In—Sn—Zn—O based semiconductor is a ternary oxide composed of In (indium), Sn (tin), and Zn (zinc). Moreover, the oxide semiconductor layer may contain an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), an Mg—Zn—O based semiconductor, an In—Ga—Sn—O based semiconductor, an In—Ga—O based semiconductor, a Zr—In—Zn—O based semiconductor, an Hf—In—Zn—O based semiconductor, or the like. Here, Al, Ti, Cd, Ge, Pb, Mg, Zr, and Hf represent aluminum, titanium, cadmium, germanium, lead, magnesium, zirconium, and hafnium, respectively.

The foregoing has been described with respect to the case where the TFT 11 included in the pixel forming portion 10 is a TFT with a channel layer which is or includes an oxide semiconductor layer. However, peripheral circuits such as source and gate drivers may also be configured by TFTs with channel layers which are or include oxide semiconductor layers.

It should be noted that this application claims priority to Japanese Patent Application No. 2015-180418, filed Sep. 14, 2015 and titled “Liquid Crystal Display Device and Method for Driving Same”, the disclosure of which is incorporated herein by reference.

### INDUSTRIAL APPLICABILITY

The present invention is applied to liquid crystal display devices capable of keeping power consumption low and preventing a polarity bias, particularly to a liquid crystal display device provided in a portable electronic apparatus.

### DESCRIPTION OF THE REFERENCE CHARACTERS

10 pixel forming portion
11 thin-film transistor
100 liquid crystal display device
200 display control portion
210 frame memory
220 selector
230 timing control circuit
231 Y-frame register
232 threshold register
233 limit counter
234 refresh counter
235 comparison circuit
236 NREF counter
237 Z-frame register
250 polarity bias management circuit
260 polarity bias value counter
270 polarity inversion control circuit
300 drive portion
310 source driver
400 gamma portion
410 positive gamma circuit
420 negative gamma circuit
500 display portion (liquid crystal panel)
GL scanning signal line
SL data signal line
Cp liquid crystal capacitor

1. A liquid crystal display device for displaying an image represented by input image data on a display portion by applying data voltages to a liquid crystal layer of the display portion in accordance with the image data, the device comprising:
a drive portion configured to apply the data voltage to the liquid crystal layer; and
a display control portion configured to manage a polarity bias of the data voltage for each predetermined period and controlling the drive portion so as to lessen the polarity bias by a forced refresh updating an image displayed on the display portion;
the display portion including a plurality of pixel forming portions configured to hold the data voltages, wherein,
when a polarity bias value indicating the polarity bias reaches a preset limit, the display control portion rewrites the data voltage held in the pixel forming portion such that the data voltage is inverted in polarity, determines whether a frequency of the polarity bias value reaching the limit satisfies a predetermined condition, and when the predetermined condition is determined to be satisfied, controls the drive portion such that the data voltage is rewritten without being inverted in polarity by the forced refresh being performed immediately after the satisfaction of the predetermined condition.

2. The liquid crystal display device according to claim 1, wherein,
the display control portion includes:
a polarity bias management circuit configured to obtain and manage the polarity bias value for each of the predetermined periods and outputs a limit-hit signal when the polarity bias value reaches the limit;
a polarity inversion control circuit configured to generate and output a polarity signal to perform control such that the polarity bias value outputted by the polarity bias management circuit approaches “0” by means of the forced refresh when the polarity bias value does not reach the limit or the polarity bias value is inverted when the polarity bias value reaches the limit; and
a timing control circuit configured to generate and provide a refresh signal to the polarity bias management circuit and the polarity inversion control circuit upon reception of a forced refresh signal for the forced refresh or generate and provide a limit refresh signal to the polarity bias management circuit and the polarity inversion control circuit upon reception of the limit-hit signal,
the timing control circuit determines whether the frequency of receiving the limit-hit signal satisfies the predetermined condition, and generates and provides an occurrence frequency signal to the polarity inversion control circuit when the predetermined condition is determined to be satisfied, and
upon provision of the occurrence frequency signal, the polarity inversion control circuit performs control such that the forced refresh in conformity with the image data is performed with the same polarity as an immediately preceding refresh.

3. The liquid crystal display device according to claim 2, wherein,
the timing control circuit includes a limit counter configured to count the number of receptions of the limit-hit signal, a threshold register configured to memorize a threshold of the number of receptions of the limit-hit signal, and a comparison circuit configured to compare the number of receptions of the limit-hit signal and the threshold, and
when the number of receptions of the limit-hit signal memorized by the limit counter is determined to be greater than or equal to the threshold memorized by the threshold register as a result of the comparison circuit comparing the number of receptions of the limit-hit signal and the threshold, the timing control circuit outputs the occurrence frequency signal to the polarity inversion control circuit.

4. The liquid crystal display device according to claim 3, wherein the timing control circuit further includes a refresh counter configured to count the number of receptions of the forced refresh signal, obtains an occurrence frequency on the basis of the number of receptions memorized by the limit counter and the number of receptions memorized by the refresh counter, compares the occurrence frequency and the threshold memorized by the threshold register by means of the comparison circuit, and when the occurrence frequency is determined to be greater than or equal to the threshold, outputs the occurrence frequency signal to the polarity inversion control circuit.

5. The liquid crystal display device according to claim 4, wherein the refresh counter counts the number of receptions of the forced refresh signal and the number of receptions of the limit refresh signal and obtains a total number of receptions.

6. The liquid crystal display device according to claim 3, wherein the timing control circuit further includes a Y-frame register configured to memorize a period of time being set as a Y-frame period, reads out the period being set as the Y-frame period from the Y-frame register, sets the Y-frame period to extend back from an arbitrary point in time within a period during which the forced refresh is performed, and determines whether the occurrence frequency is greater than or equal to the threshold during the Y-frame period.

7. The liquid crystal display device according to claim 2, wherein,
the timing control circuit includes a Z-frame register configured to memorize a period of time being set as a Z-frame period, and
upon reception of a limit refresh signal from the polarity bias management circuit, the timing control circuit reads out the period being set as the Z-frame period from the Z-frame register, sets the Z-frame period to extend forward, and upon reception of an initial limit refresh signal during the Z-frame period, outputs the occurrence frequency signal to the polarity inversion control circuit.

8. The liquid crystal display device according to claim 2, wherein the polarity bias management circuit includes a balance counter configured to count and hold the polarity bias value, and increases or decreases the polarity bias value held in the balance counter by “1” as specified by the polarity signal upon each provision of a vertical synchronization signal to display an image represented by the image data on the display portion.

9. The liquid crystal display device according to claim 2, further comprising a positive gamma circuit configured to generate positive image data on the basis of the image data and a negative gamma circuit configured to generate negative image data on the basis of the input image data, wherein,
the display control portion further includes a selector configured to select either the positive gamma circuit or the negative gamma circuit, and
the selector selects either the positive gamma circuit or the negative gamma circuit in accordance with the polarity signal provided by the polarity inversion control circuit, and provides the input image data so as not to cause a polarity bias in each of the pixel forming portions.

10. The liquid crystal display device according to claim 9, wherein,
the display control portion further includes frame memory configured to store the input image data,
the timing control circuit outputs the refresh signal to the polarity inversion control circuit and the polarity bias management circuit, and provides the frame memory with a readout signal to read out the image data, and
the frame memory outputs to the selector the image data having already been stored upon provision of the readout signal.

11. The liquid crystal display device according to claim 2, further comprising data signal lines and scanning signal lines formed on the display portion so as to connect the pixel forming portions and the drive portion, wherein,
the pixel forming portion includes:
a pixel capacitor configured to hold the data voltage; and
a switching element with a control terminal connected to the scanning signal line, a first conductive terminal connected to the data signal line, and a second conductive terminal connected to the pixel capacitor, and
the switching element includes a thin-film transistor with a channel layer formed with an oxide semiconductor.

12. The liquid crystal display device according to claim 11, wherein the pixel forming portion includes a thin-film transistor with an oxide semiconductor layer.

13. The liquid crystal display device according to claim 12, wherein the thin-film transistor is a channel-etched thin-film transistor.

14. The liquid crystal display device according to claim 12, wherein the oxide semiconductor layer is formed with indium gallium zinc oxide.

15. The liquid crystal display device according to claim 12, wherein the oxide semiconductor layer is formed with a crystalline oxide semiconductor.

16. The liquid crystal display device according to claim 12, wherein the oxide semiconductor layer has a stack structure.

17. A method for driving a liquid crystal display device displaying an image represented by input image data on a display portion by applying data voltages to a liquid crystal layer of the display portion in accordance with the image data, the device including a drive portion configured to apply the data voltage to the liquid crystal layer, and a display control portion configured to manage a polarity bias of the data voltage for each predetermined period and controlling the drive portion so as to lessen the polarity bias of the data voltage during a frame period in which the image displayed on the display portion is updated, the display portion including a plurality of pixel forming portions configured to hold the data voltages, the method comprising the steps of:
when a polarity bias value indicating the polarity bias reaches a preset limit, rewriting the data voltage held in the pixel forming portion such that the data voltage is inverted in polarity;
determining whether the polarity bias value satisfies a predetermined condition; and
when the predetermined condition is determined to be satisfied, controlling the drive portion such that the data voltage is rewritten without being inverted in polarity by a forced refresh being performed immediately after a limit refresh, in accordance with updating the image data.
